(19) United States
(12) Patent Application Publication
(10) Pub. No.: US 2026/0020306 A1
(43) Pub. Date: Jan. 15, 2026

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventor: Chih-Yang CHEN, Hsinchu City (TW)

(21) Appl. No.: 18/769,638

(22) Filed: Jul. 11, 2024

(51) Int. Cl. H01L 29/66; H01L 29/06; H01L 29/423; H01L 29/775; H01L 29/786

(52) U.S. Cl. CPC H10D 64/017; H10D 30/014; H10D 30/43; H10D 30/6735; H10D 30/6757; H10D 62/121; H10D 64/018

(57) ABSTRACT

Semiconductor structures and methods for manufacturing the same are provided. The semiconductor structure includes a plurality of first nanostructures formed over a substrate, and a first gate structure formed over the first nanostructures. The semiconductor structure includes a gate spacer layer formed adjacent to the first gate structure, and a nitride layer formed adjacent to the first gate structure. The nitride layer is directly below the gate spacer layer and the nitrogen concentration of the nitride layer gradually decreases from the outer sidewall surface to the inner sidewall surface.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A to 1D illustrate perspective views of intermediate stages of manufacturing a semiconductor structure in accordance with some embodiments.

FIGS. 2A-1 to 2K-1 illustrate cross-sectional representations of various stages of manufacturing the semiconductor structure shown along line X-X′ in FIG. 1D, in accordance with some embodiments.

FIGS. 2A-2 to 2K-2 illustrate cross-sectional representations of various stages of manufacturing the semiconductor structure shown along line Y-Y′ in FIG. 1D, in accordance with some embodiments.

FIGS. 2A-3 to 2K-3 illustrate plane views of various stages of manufacturing the semiconductor structure shown along plane C-C′ in FIGS. 2A-1 to 2K-1 and in FIGS. 2A-2 to 2K-2, in accordance with some embodiments.

FIG. 2K′-1 illustrates a cross-sectional view of a semiconductor structure, in accordance with some embodiments.

FIG. 2C-4 is an enlarged cross-sectional view of the nitride layer of FIG. 2C-1, in accordance with some embodiments.

FIGS. 3A-1 to 3O-1 illustrate cross-sectional representations of various stages of manufacturing a semiconductor structure along a first direction (similar to line A-A′) of FIG. 1D, in accordance with some embodiments.

FIGS. 3A-2 to 3O-2 illustrate cross-sectional representations of various stages of manufacturing the semiconductor structure along a second direction (similar to line B-B′ of FIG. 1D), in accordance with some embodiments.

FIG. 4 show perspective views of a semiconductor structure, in accordance with some embodiments.

FIG. 5A-1 shows the cross-sectional representation shown along line A-A′ in FIG. 4, in accordance with some embodiments.

FIG. 5A-2 shows the cross-sectional representation shown along line B-B′ in FIG. 4, in accordance with some embodiments.

FIG. 6A-1 shows the cross-sectional representation shown along line A-A′ in FIG. 4, in accordance with some embodiments.

FIG. 6A-2 shows the cross-sectional representation shown along line B-B′ in FIG. 4, in accordance with some embodiments.

FIG. 6A-3 shows the cross-sectional representation shown along line C-C′ in FIG. 4, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of semiconductor structures and methods for forming the same are provided. The semiconductor structures may include a fin structure formed over a substrate. The fin structure includes nanostructures. A gate structure formed over the first nanostructures and a first S/D structure adjacent to the gate structure. A gate spacer layer is adjacent to the gate structure, and a nitride layer is directly below the gate spacer layer. The composition of the nitride layer is different from that of the gate spacer layer. The nitride layer is formed by performing a nitridation process on the dummy gate dielectric layer. The nitride layer is not removed during the dummy gate dielectric layer is removed. The gate structure is separated from the S/D structure by the nitride layer and the gate spacer layer. The risk of the leakage between the gate structure and the S/D structure is reduced due to the formation of the nitride layer. Therefore, the performance and the reliability of the semiconductor structure is improved. The nitride layer can be used in GAA device, the CFET device or fork-sheet device. The source/drain (S/D) structure or region(s) may refer to a source or a drain, individually or collectively dependent upon the context.

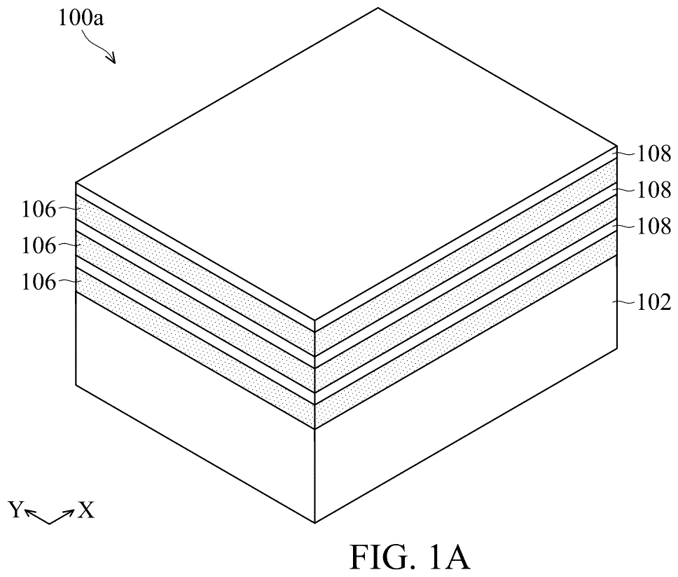

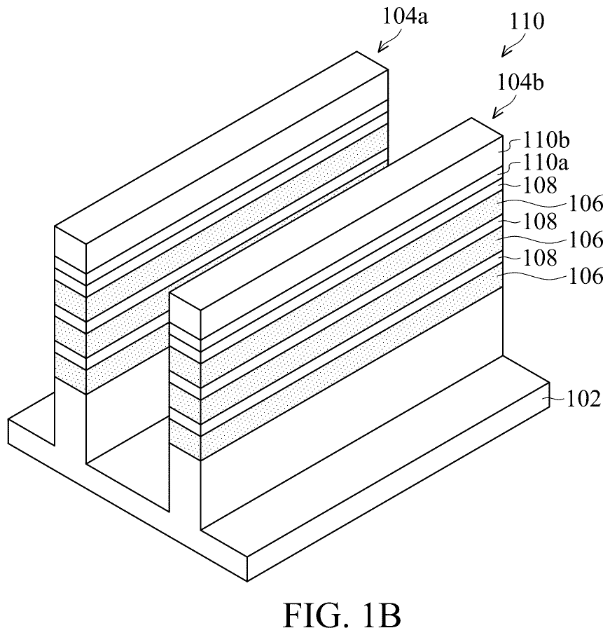

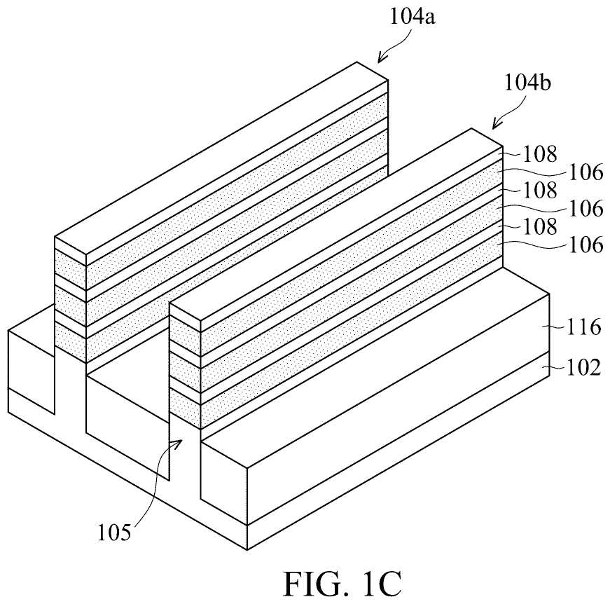

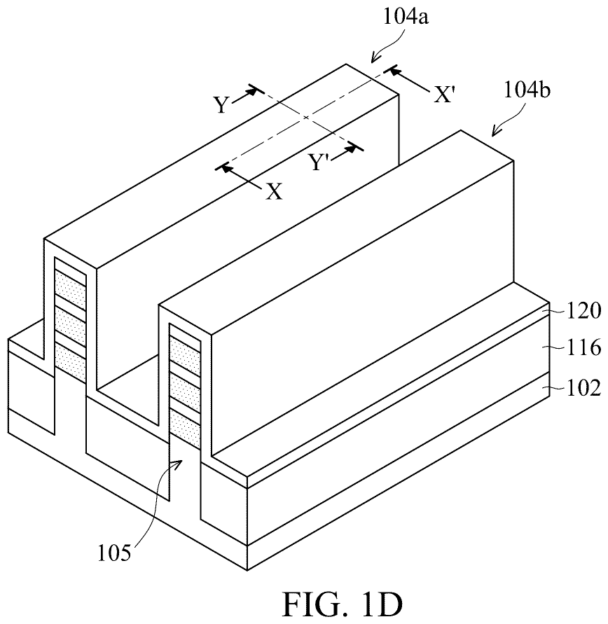

FIGS. 1A to 1D illustrate perspective views of intermediate stages of manufacturing a semiconductor structure 100a, in accordance with some embodiments. As shown in FIG. 1A, first semiconductor material layers 106 and second semiconductor material layers 108 are formed over a substrate 102.

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102. In some embodiments, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although three first semiconductor material layers 106 and three second semiconductor material layers 108 are formed, the semiconductor structure may include more or fewer first semiconductor material layers 106 and second semiconductor material layers 108. For example, the semiconductor structure may include two to five of the first semiconductor material layers 106 and the second semiconductor material layers.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

Afterwards, as shown in FIG. 1B, after the first semiconductor material layers 106 and the second semiconductor material layers 108 are formed as a semiconductor material stack over the substrate 102, the semiconductor material stack is patterned to form a first fin structure 104a and a second fin structure 104b, in accordance with some embodiments. In some embodiments, each of the first fin structure 104a and a second fin structure 104b includes a base fin structure 105 and the semiconductor material stack of the first semiconductor material layers 106 and the second semiconductor material layers 108.

In some embodiments, the patterning process includes forming a mask structure 110 over the semiconductor material stack, and etching the semiconductor material stack and the underlying substrate 102 through the mask structure 110. In some embodiments, the mask structure 110 is a multilayer structure including a pad oxide layer 110a and a nitride layer 110b formed over the pad oxide layer 110a. The pad oxide layer 110a may be made of silicon oxide, which is formed by thermal oxidation or chemical vapor deposition (CVD), and the nitride layer 110b may be made of silicon nitride, which is formed by chemical vapor deposition (CVD), such as low-temperature chemical vapor deposition (LPCVD) or plasma-enhanced CVD (PECVD).

Next, as shown in FIG. 1C, after the first fin structure 104a and the second fin structure 104b is formed, an isolation structure 116 is formed around first fin structure 104a and the second fin structure 104b, and the mask structure 110 is removed, in accordance with some embodiments. The isolation structure 116 is configured to electrically isolate active regions (e.g. the first fin structure 104a and the second fin structure 104b) of the semiconductor structure 100a and is also referred to as shallow trench isolation (STI) feature in accordance with some embodiments.

The isolation structure 116 may be formed by depositing an insulating layer over the substrate 102 and recessing the insulating layer so that the first fin structure 104a and the second fin structure 104b protrude from the isolation structure 116. In some embodiments, the isolation structure 116 is made of silicon oxide, silicon nitride, silicon oxynitride (SiON), another suitable insulating material, or a combination thereof. In some embodiments, a dielectric liner (not shown) is formed before the isolation structure 116 is formed, and the dielectric liner is made of silicon nitride and the isolation structure formed over the dielectric liner is made of silicon oxide.

Afterwards, as shown in FIG. 1D, after the isolation structure 116 is formed, a dummy gate dielectric layer 120 is formed on the first fin structure 104a and the second fin structure 104b, in accordance with some embodiments. In some embodiments, the dummy gate dielectric layers 120 are made of one or more dielectric materials, such as silicon oxide, silicon nitride, silicon oxynitride (SiON), HfO₂, HfZrO, HfSiO, HfTIO, HfAlO, or a combination thereof. In some embodiments, the dummy gate dielectric layers 120 are formed using thermal oxidation, chemical vapor deposition (CVD), atomic vapor deposition (ALD), physical vapor deposition (PVD), another suitable method, or a combination thereof.

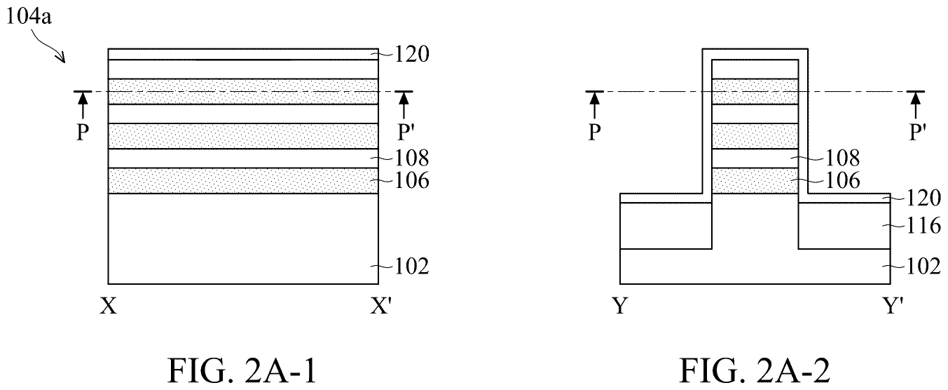

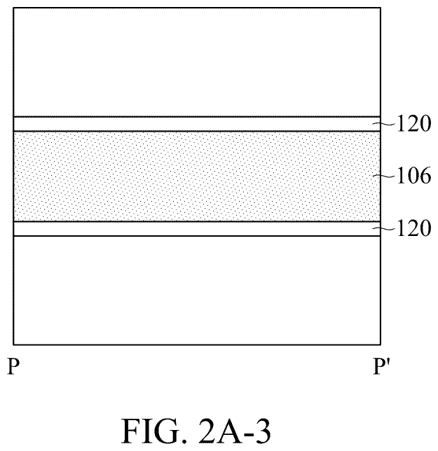

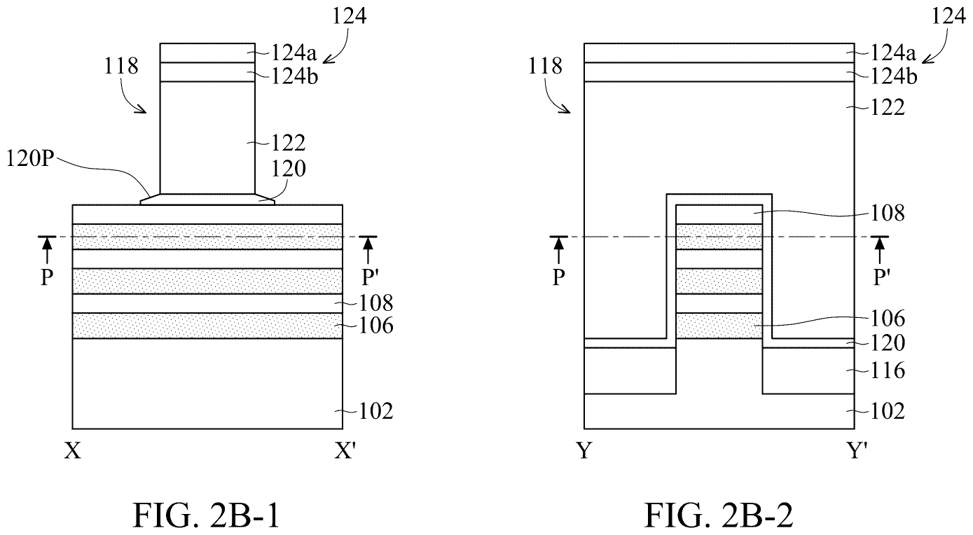

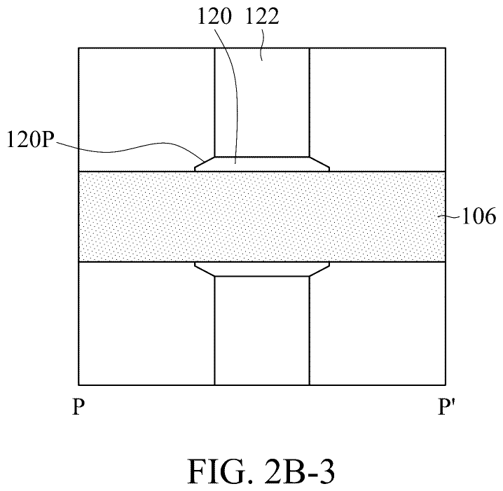

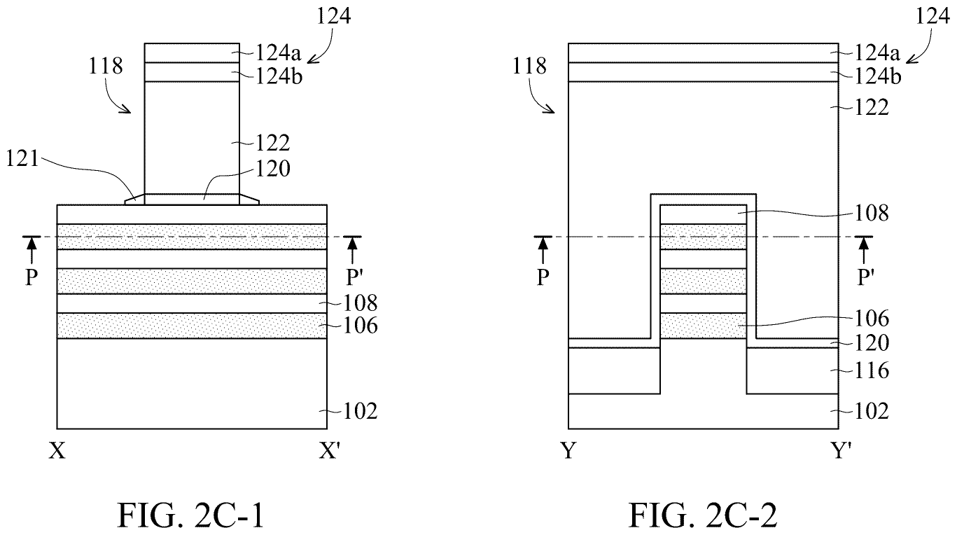

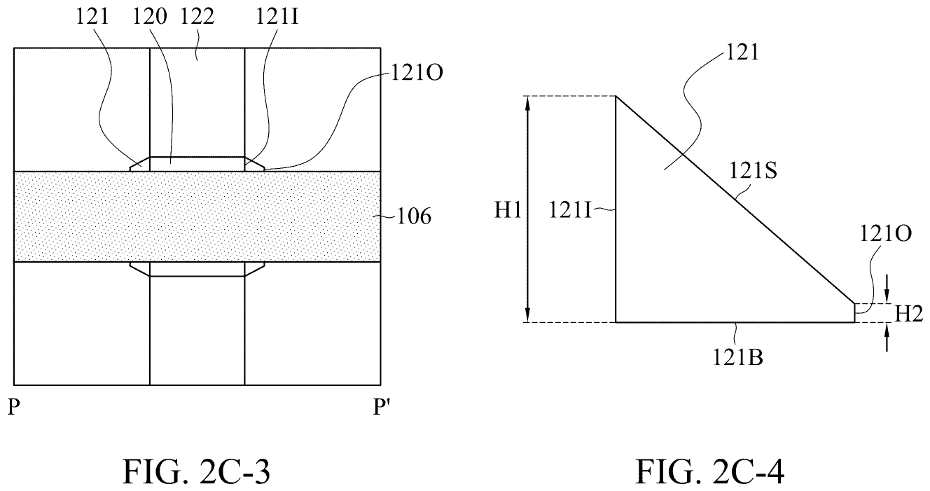

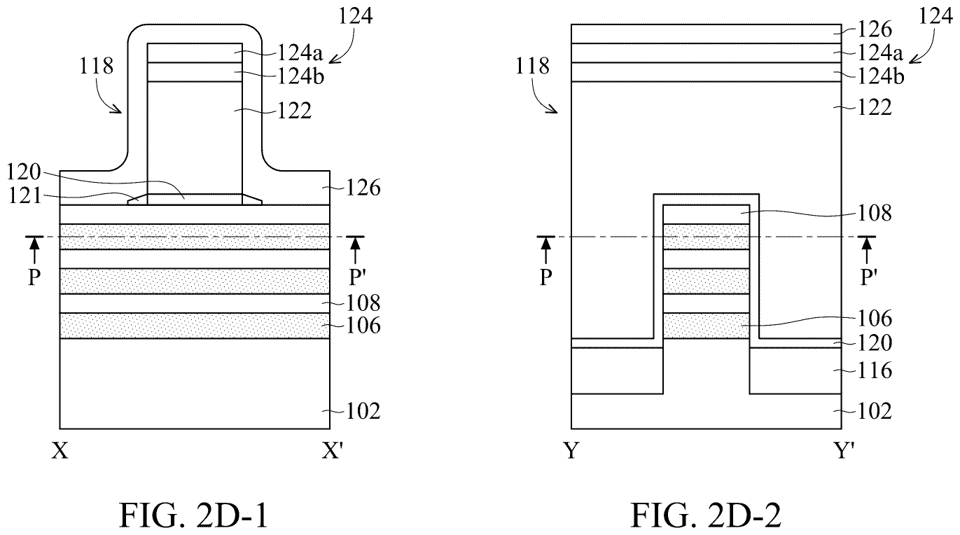

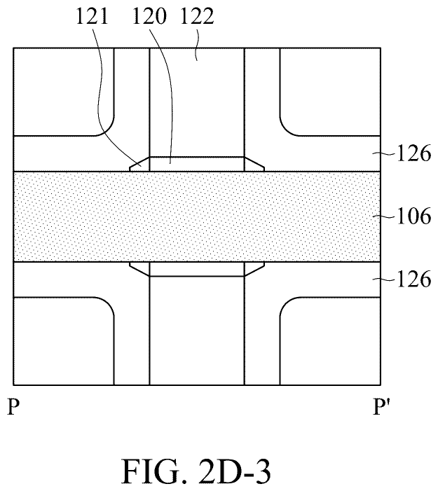

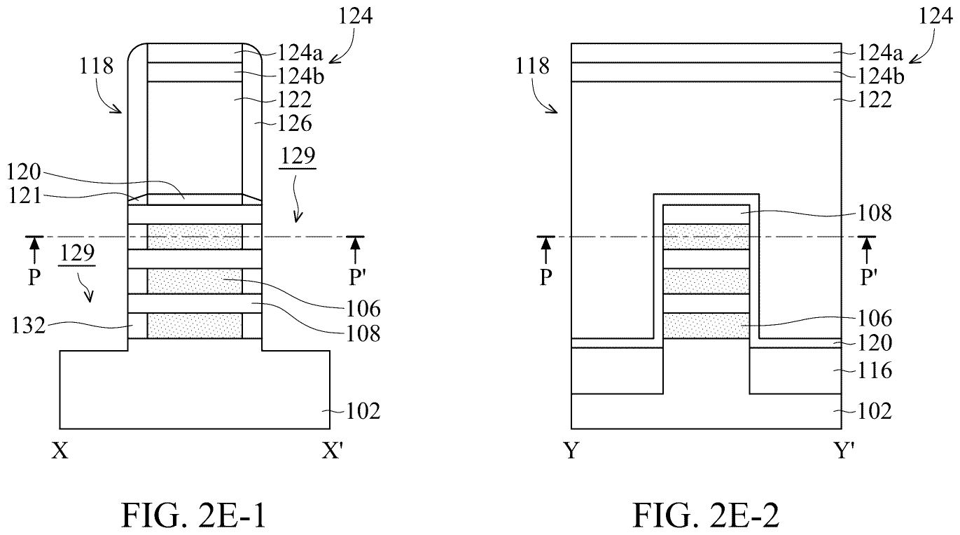

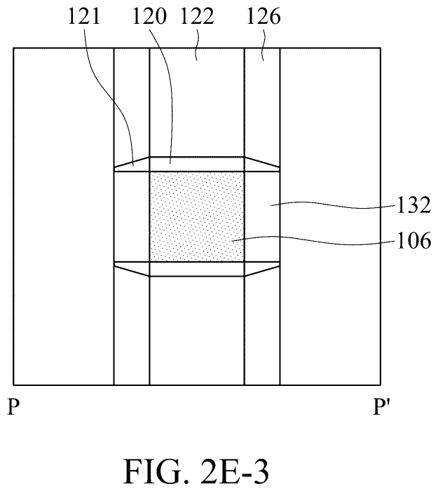

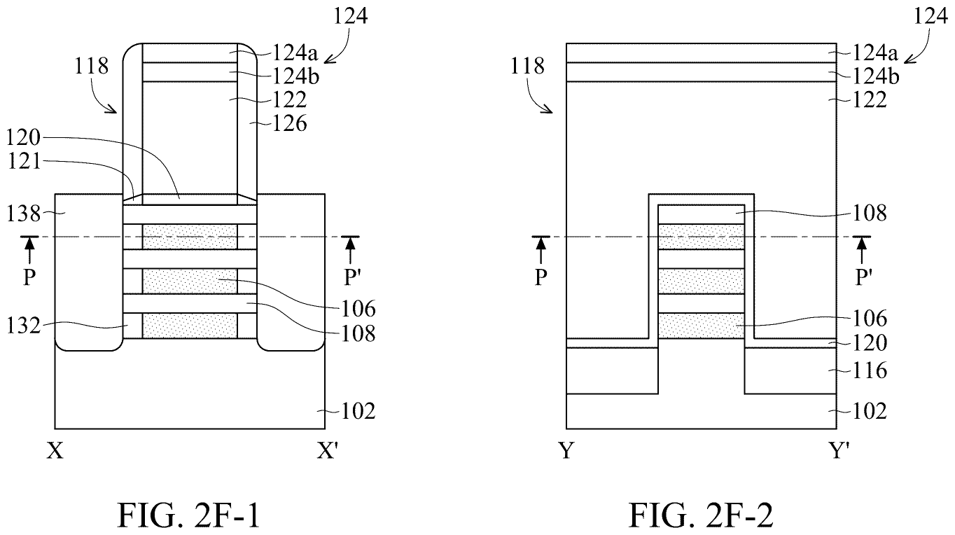

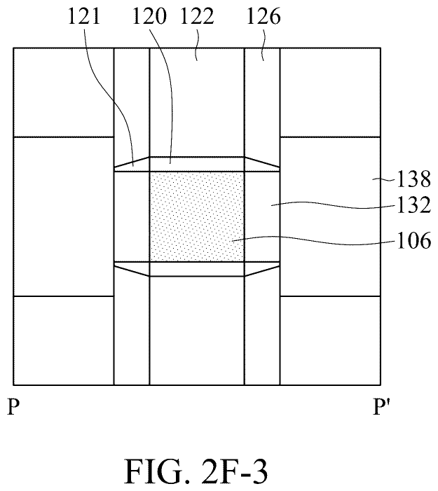

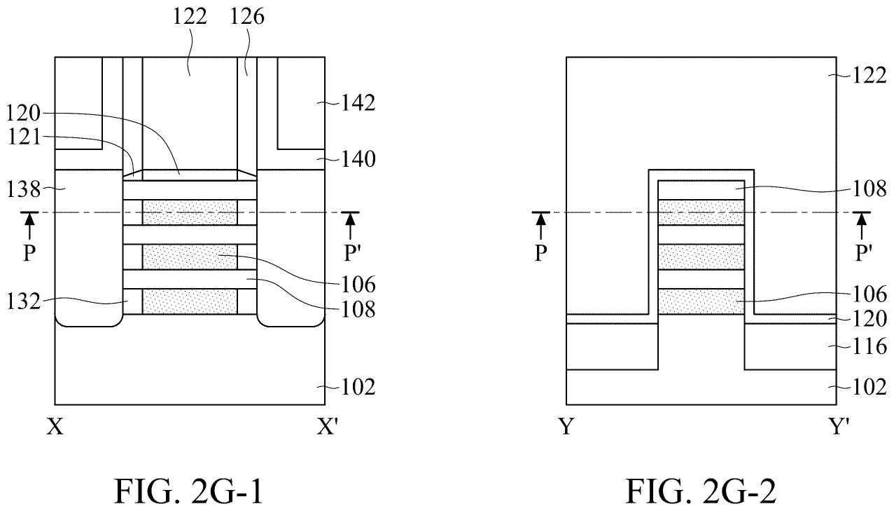

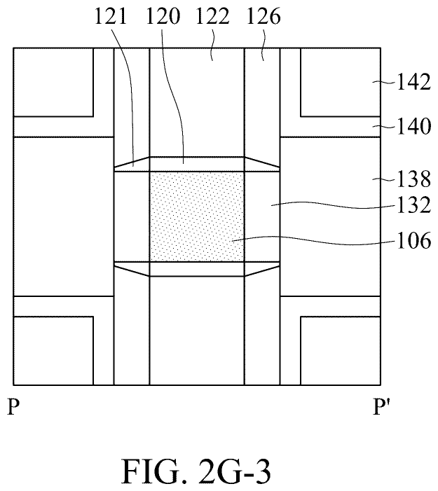

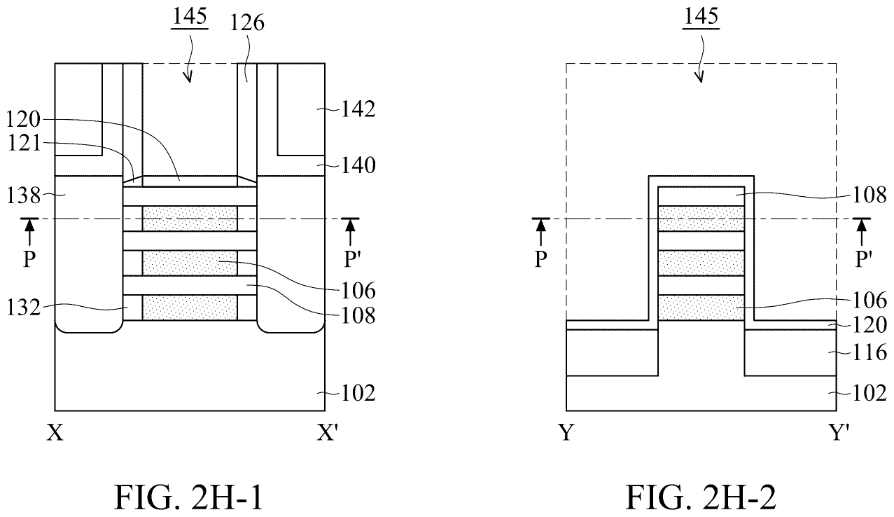

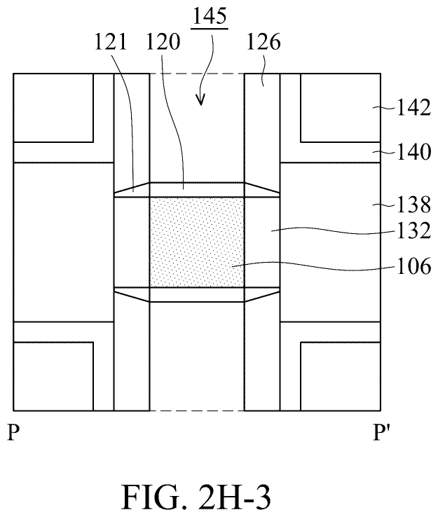

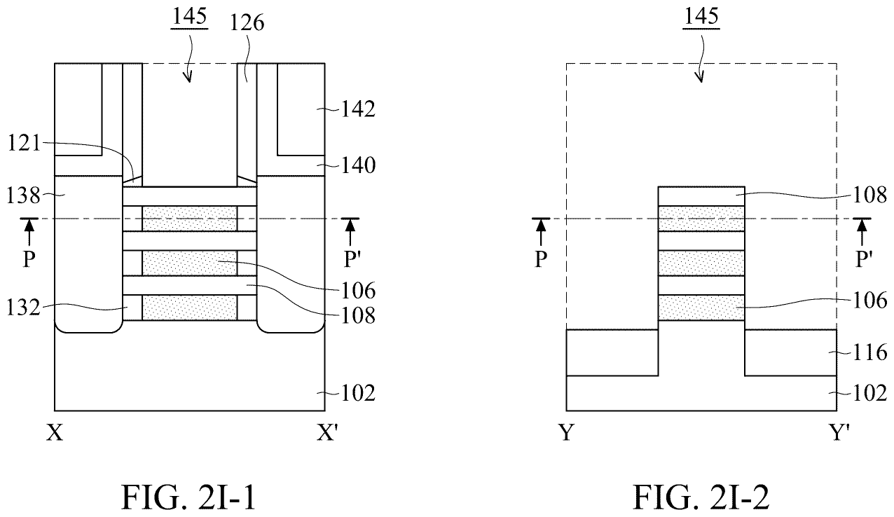

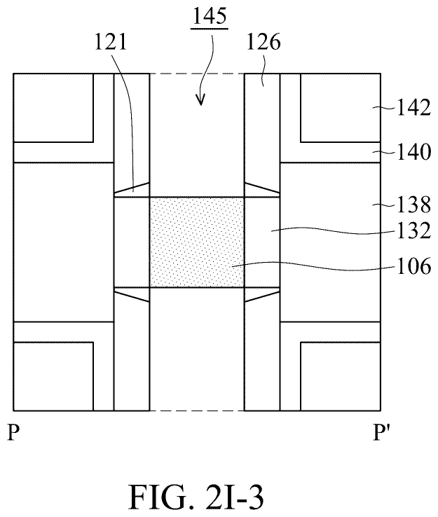

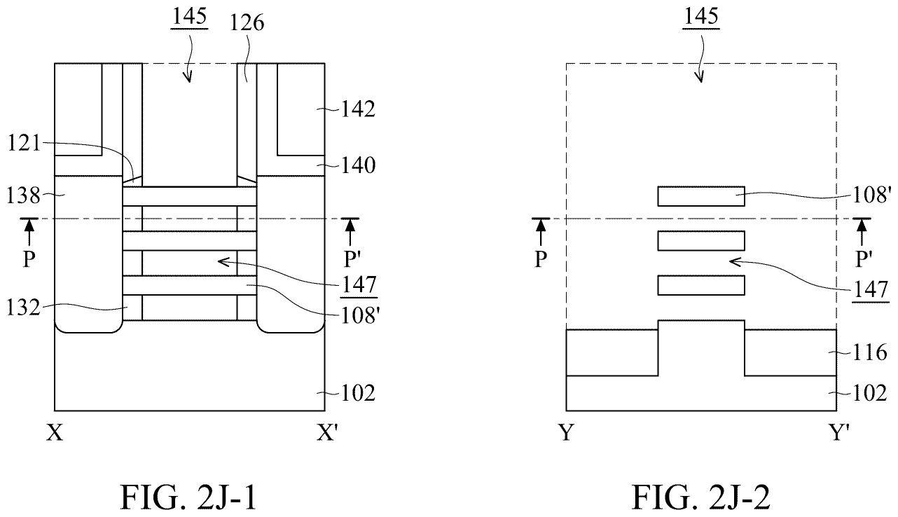

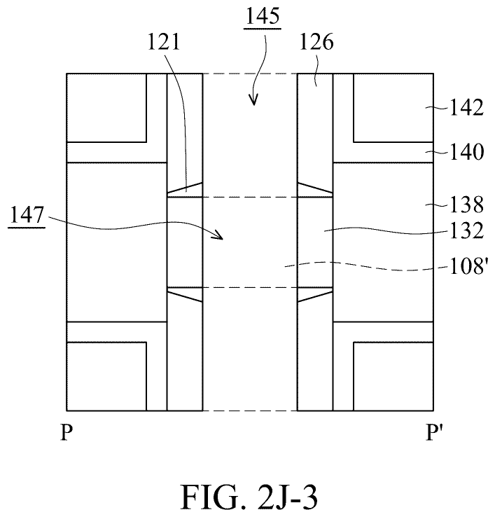

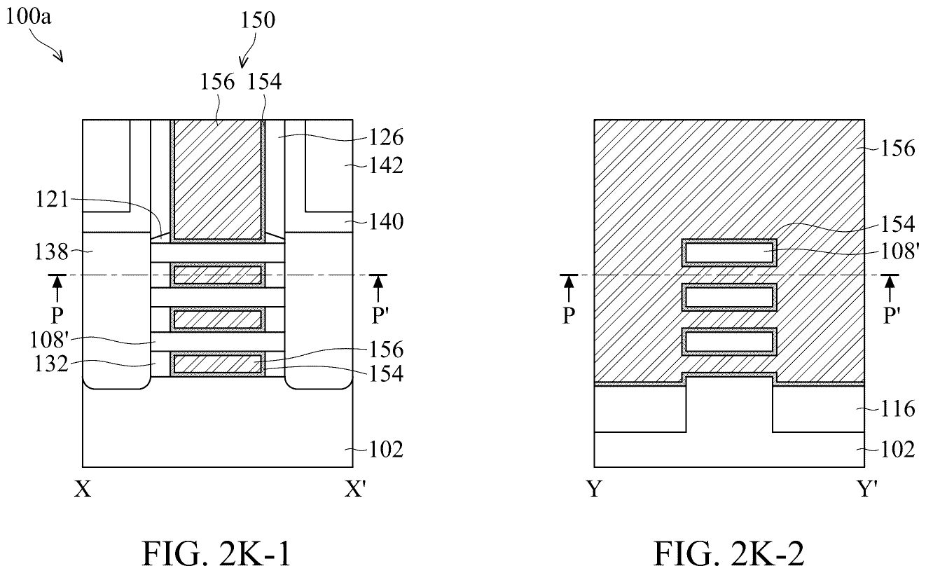

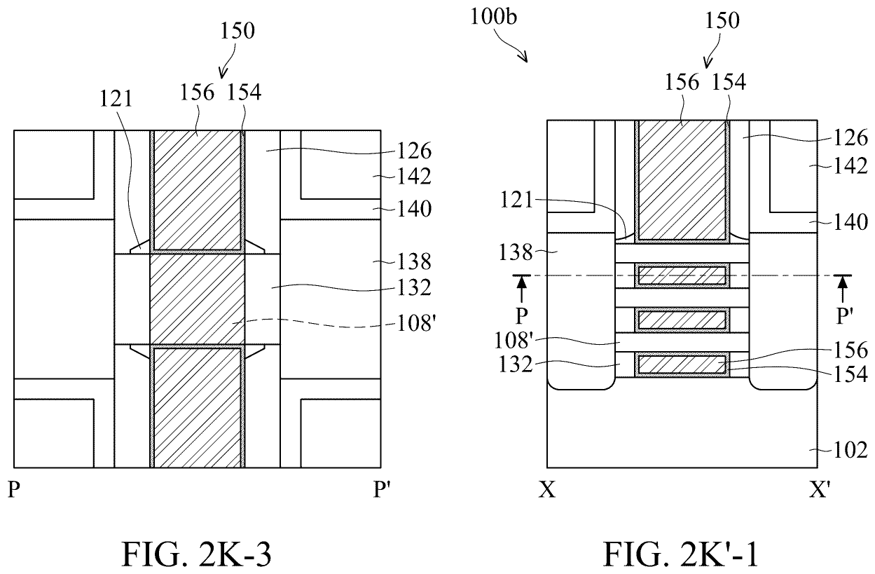

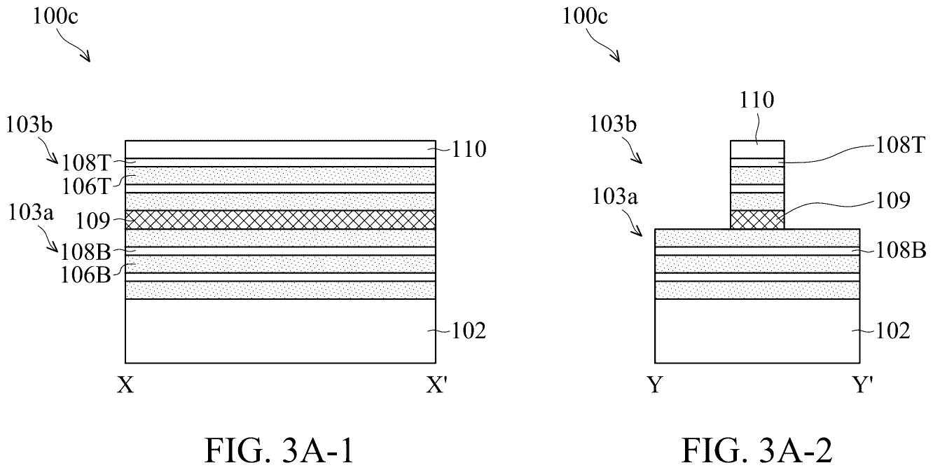

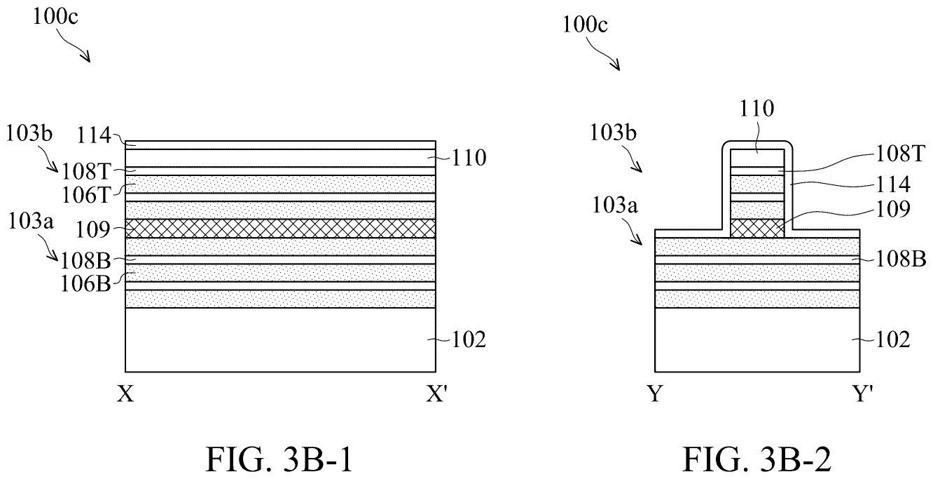

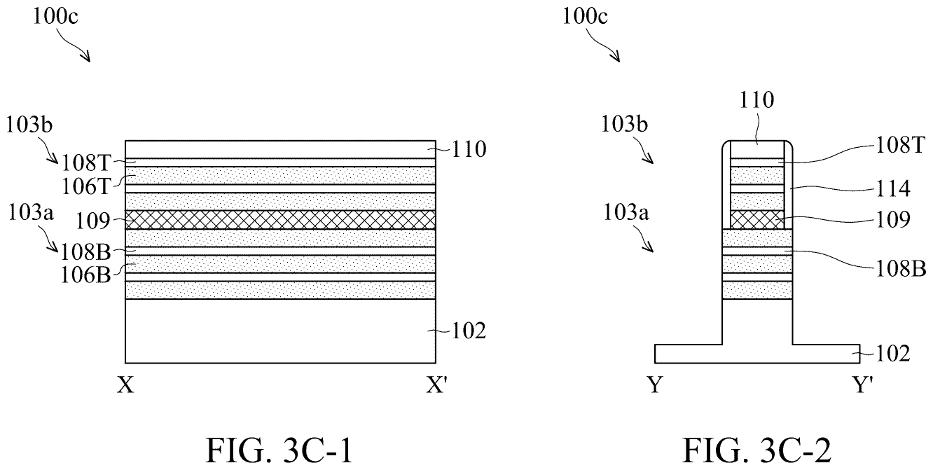

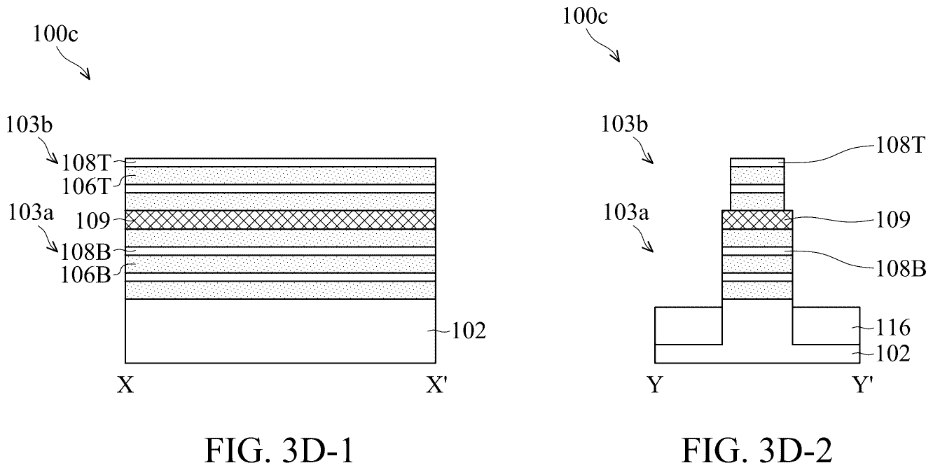

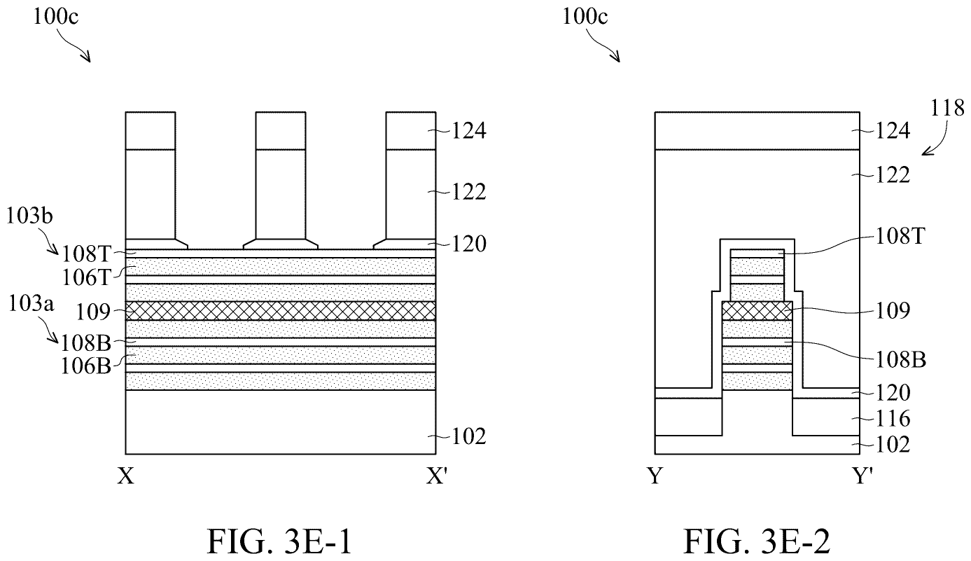

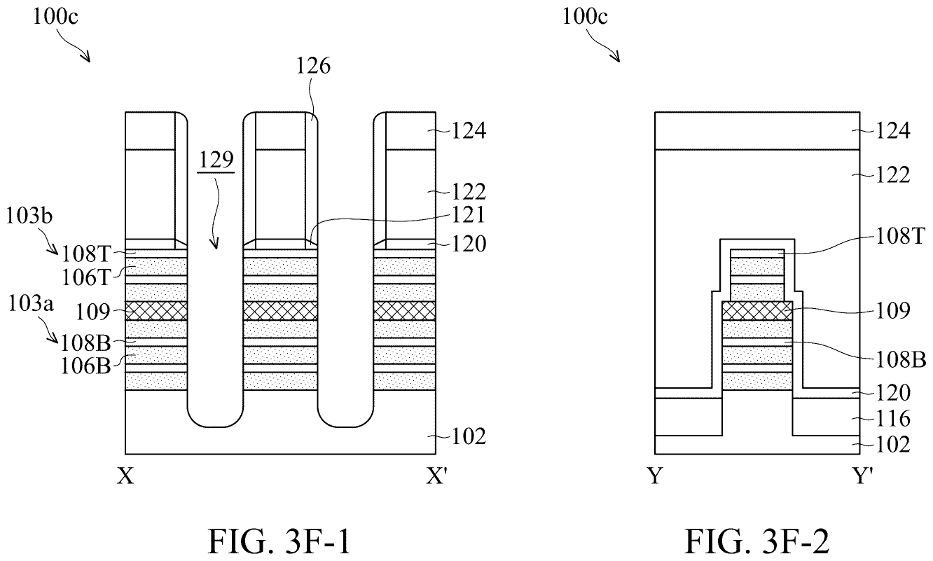

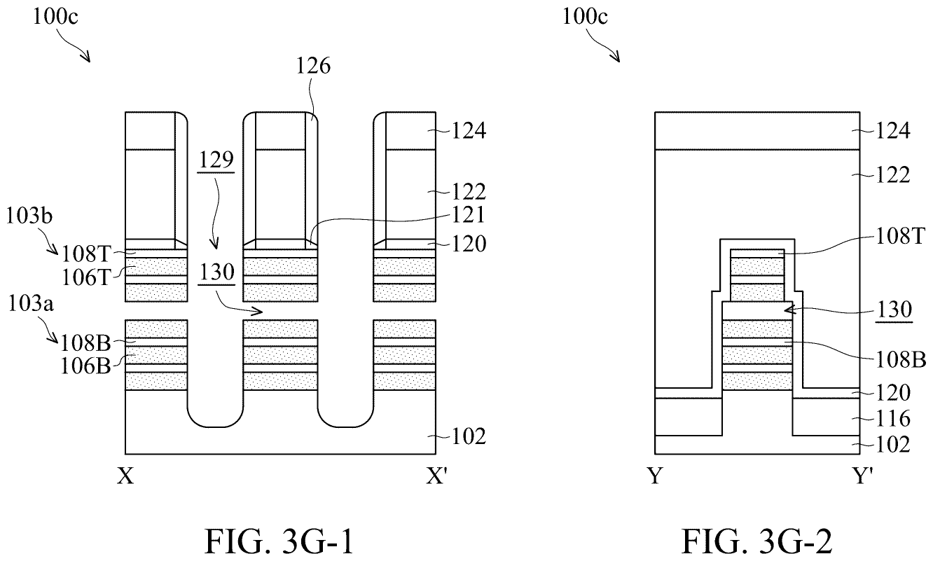

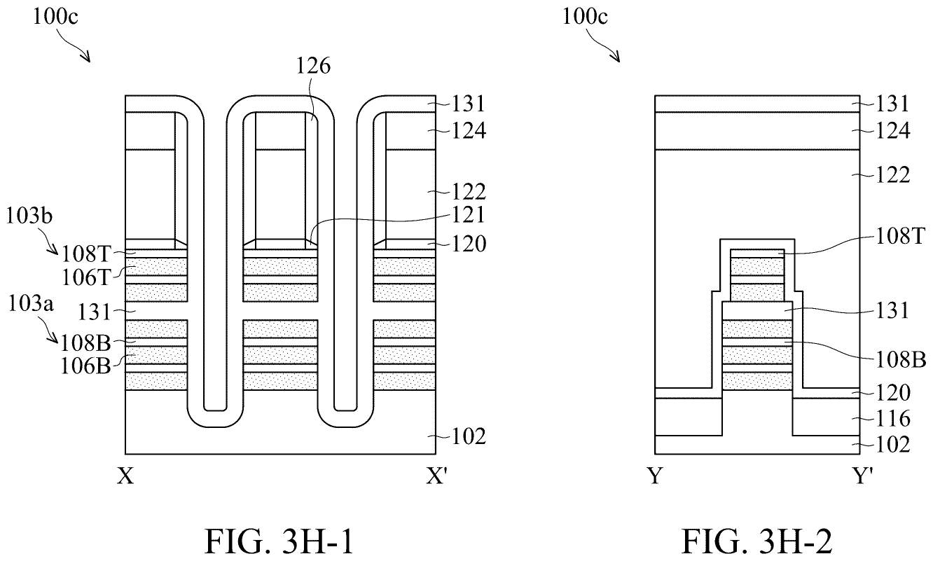

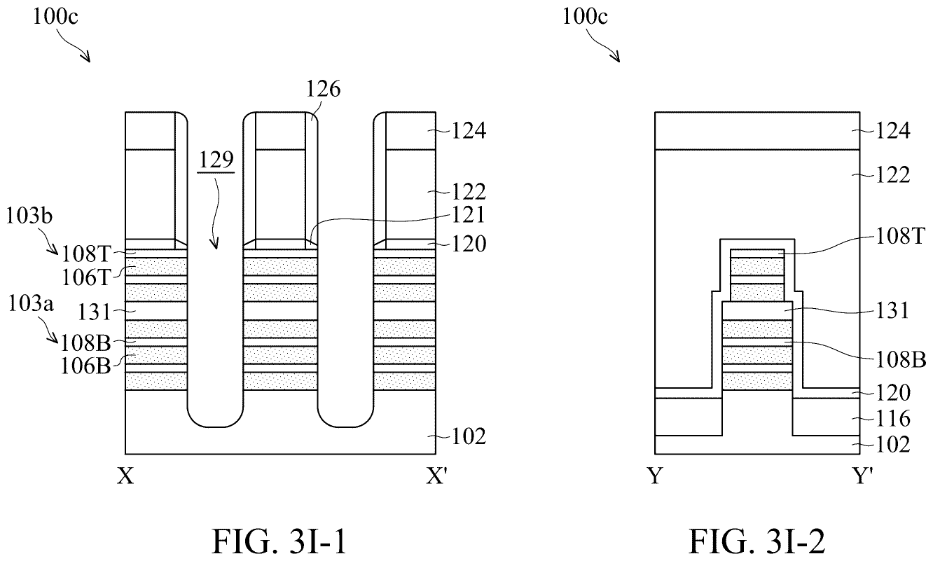

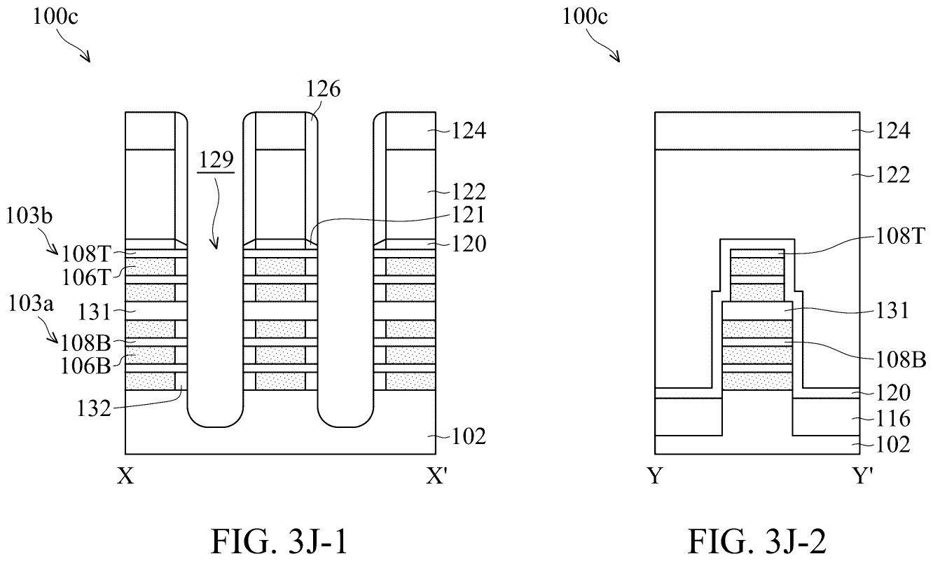

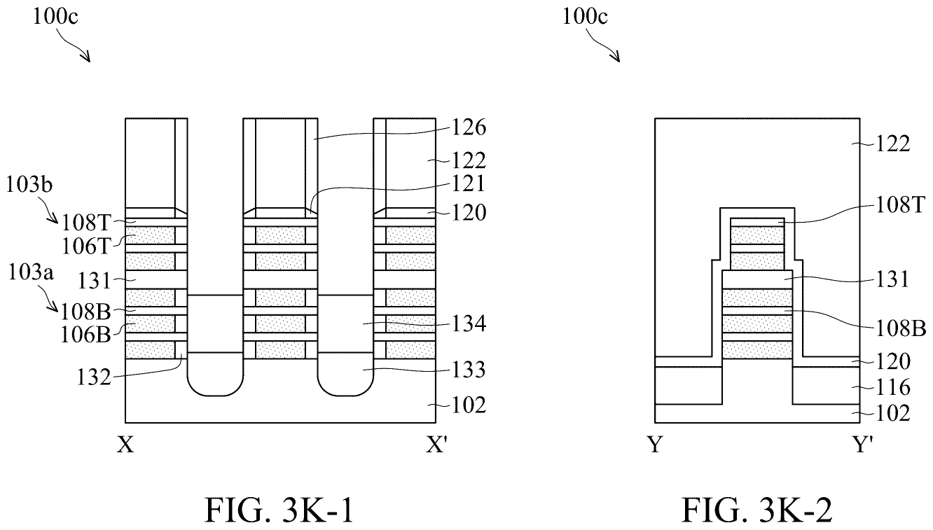

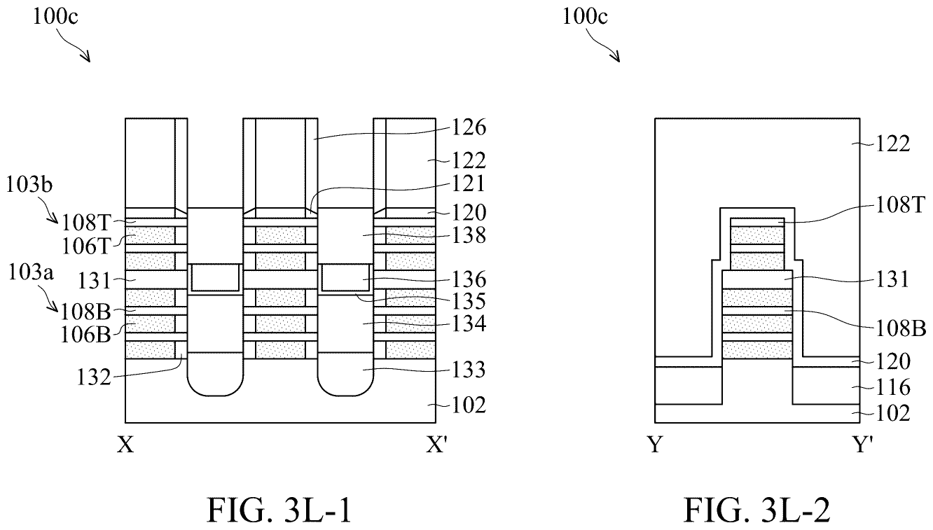

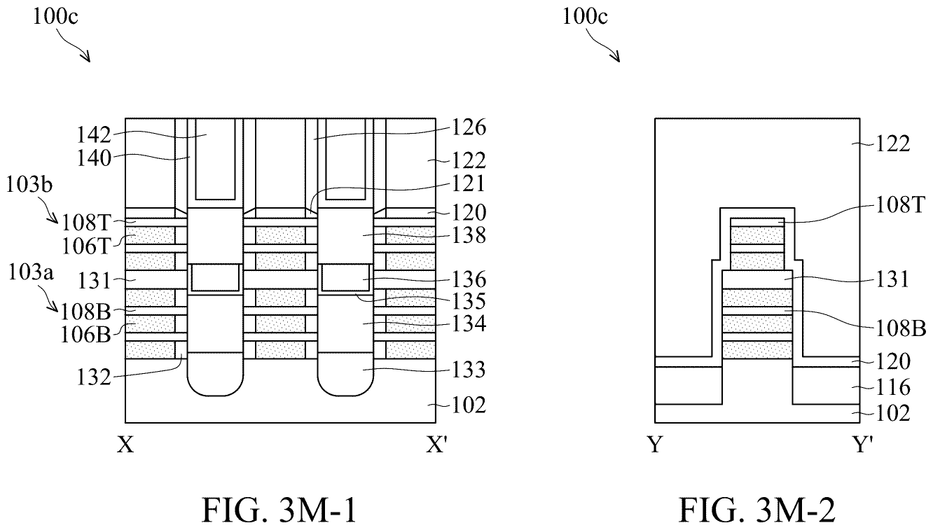

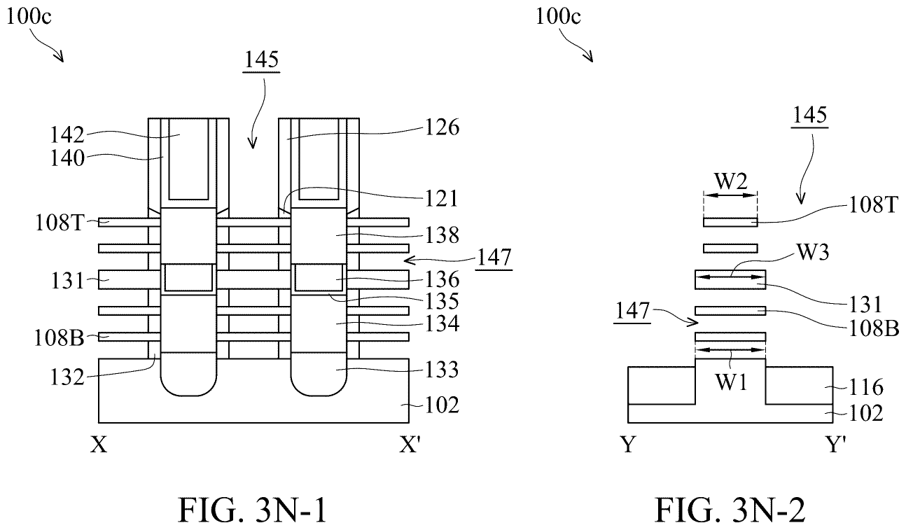

FIGS. 2A-1 to 2K-1 illustrate cross-sectional representations of various stages of manufacturing the semiconductor structure 100a shown along line X-X′ in FIG. 1D, in accordance with some embodiments. FIGS. 2A-2 to 2K-2 illustrate cross-sectional representations of various stages of manufacturing the semiconductor structure 100a shown along line Y-Y′ in FIG. 1D, in accordance with some embodiments. FIGS. 2A-3 to 2K-3 illustrate plane views of various stages of manufacturing the semiconductor structure 100a shown along plane P-P′ in FIGS. 2A-1 to 2K-1 and in FIGS. 2A-2 to 2K-2, in accordance with some embodiments.

More specifically, FIG. 2A-1 illustrates the cross-sectional representation shown along line X-X′ in FIG. 1D, in accordance with some embodiments. FIG. 2A-2 illustrates the cross-sectional representation shown along line Y-Y′ in FIG. 1D, in accordance with some embodiments. FIG. 2A-3 illustrates the cross-sectional representation shown along line P-P′ in FIGS. 2A-1 and 2A-2, in accordance with some embodiments.

Next, as shown in FIGS. 2B-1, 2B-2 and 2B-3, after the dummy gate dielectric layer 120 is formed, the dummy gate electrode layer 122 is formed on the dummy gate dielectric layer 120, in accordance with some embodiments.

Next, a hard mask layer 124 is formed over the dummy gate structures 118. In some embodiments, the hard mask layer 124 include a first layer 124a and a second layer 124b. In some embodiments, the first layer 124a is an oxide layer and the second layer 124b is a nitride layer. In some embodiments, the oxide layer is silicon oxide, and the nitride layer is silicon nitride.

The dummy gate electrode layer 122 and the dummy gate dielectric layer 120 are patterned by using the hard mask layer 124 as a mask to form a dummy gate structure 118.

The dummy gate structure 118 formed across the first fin structure 104a and the second fin structure 104b and extend over the isolation structure 116, in accordance with some embodiments. The dummy gate structures 118 may be used to define the source/drain (S/D) regions and the channel regions of the resulting semiconductor structure 100a.

The dummy gate structure 118 includes dummy gate dielectric layer 120 and dummy gate electrode layer 122. In some embodiments, the dummy gate electrode layer includes polycrystalline-silicon (poly-Si), poly-crystalline silicon-germanium (poly-SiGe), metallic nitrides, metallic silicides, metals, or a combination thereof. In some embodiments, the dummy gate electrode layer 122 is formed using chemical vapor deposition (CVD), physical vapor deposition (PVD), or a combination thereof.

The formation of the dummy gate structures 118 may include patterning the dummy gate electrode layer 122 and the dummy gate dielectric layer 120 to form a patterned dummy gate electrode layer and a patterned dummy gate dielectric layer. It should be noted that the patterned dummy gate dielectric layer 120 includes a protruding portion 120P, and the protruding portion 120P of the dummy gate dielectric layer 120 protrudes from the sidewall surface of the patterned dummy gate electrode layer 122.

Afterwards, as shown in FIGS. 2C-1, 2C-2 and 2C-3, after patterning the dummy gate electrode layer 122 and the dummy gate dielectric layer 120, a nitridation process is performed on the protruding portion 120P of the dummy gate dielectric layer 120, in accordance with some embodiments. As a result, the protruding portion 120P of the dummy gate dielectric layer 120 becomes a nitride layer 121. The nitridation process is configured to change the composition of the protruding portion 120P of the dummy gate dielectric layer 120.

In some embodiments, the nitride layer 121 includes silicon nitride (SiN), silicon oxynitride (SiON), silicon carbon nitride (SiCN), silicon oxycarbonitride (SiOCN), and/or a combination thereof.

Note that after the nitridation process, the composition of the nitride layer 121 and that of the dummy gate dielectric layer 120 are different. In some embodiments, the nitride layer 121 has a quadrilateral shaped structure. In some embodiments, the nitride layer 121 has a triangular shaped structure.

FIG. 2C-4 is an enlarged cross-sectional view of the nitride layer 121 of FIG. 2C-1, in accordance with some embodiments.

As shown in FIGS. 2C-1 and 2C-4, the nitride layer 121 has an inner sidewall surface 121I, an outer sidewall surface 121O, a lateral sidewall surface 121S between the inner sidewall surface 121I and the outer sidewall surface 121O and a bottom surface 121B. The bottom surface 121B of the nitride layer 121 is in direct contact with the topmost second semiconductor material layer 108. The inner sidewall surface 121I is in direct contact with the dummy gate dielectric layer 120. In some embodiments, the nitrogen concentration of the nitride layer 121 gradually decreases from the outer sidewall surface 121O to the inner sidewall surface 121I.

In some embodiments, the inner sidewall surface 121I of the nitride layer 121 has a first height H₁ along the vertical direction, and the outer sidewall surface of 121O of the nitride layer 121 has a second height H2 along the vertical direction. In some embodiments, the first height H1 is greater than the second height H2.

After the nitridation process, the nitride layer 121 is formed, and the nitride layer 121 is not easily be removed by etching process in subsequent steps than the dummy gate dielectric layer 120. In a compared embodiment, if the protruding portion 120P of the dummy gate dielectric layer 120 is removed by an etching process to form a recess, the metal gate structure (formed later) may be formed in recess, and the metal gate structure may be in direct contacts with the S/D structure. Therefore, an unwanted leakage may occur. In order to reduce the risk of the leakage, the protruding portion 120P of the dummy gate dielectric layer 120 is treated by nitridation process to form the nitride layer 121. The etching resistance of the nitride layer 121 is better than that of the dummy gate dielectric layer 120.

In some embodiments, a nitrogen-containing plasma is used in the nitridation process. In some embodiments, a nitrogen-containing implant process is used in the nitridation process.

Afterwards, as shown in FIGS. 2D-1, 2D-2 and 2D-3, after the nitride layer 121 is formed, a gate spacer layer 126 is formed along and covering opposite sidewalls of the dummy gate structure 118, in accordance with some embodiments. The gate spacer layers 126 may be configured to separate source/drain (S/D) structures from the dummy gate structure 118 and support the dummy gate structure 118.

In some embodiments, the gate spacer layer 126 includes a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. The formation of the gate spacer layers 126 and may include conformally depositing a dielectric material covering the dummy gate structure 118, the first fin structure 104a, the second fin structure 104b and the isolation structure 116 over the substrate 102, and performing an anisotropic etching process, such as dry plasma etching, to remove the dielectric layer covering the top surfaces of the dummy gate structure 118, the first fin structure 104a, the second fin structure 104b, and portions of the isolation structure 116.

Next, as shown in FIGS. 2E-1, 2E-2 and 2E-3, after the gate spacer layers 126 is formed, a portion of the gate spacer layer is removed, in in accordance with some embodiments. The gate spacer layers 126 is directly on the nitride layer 121.

In some embodiments, the sidewall surface of the nitride layer 121 is aligned with the sidewall surface of the gate spacer layer 126. More specifically, the inner sidewall surface 121I of the nitride layer 121 is aligned with the inner sidewall surface of the gate spacer layer 126. The inner sidewall surface 121I of the nitride layer 121 is vertical to the top surface of the second semiconductor material layers 108. In some embodiments, the lateral sidewall surface of 121S of the nitride layer 121 is not vertical to the top surface of the second semiconductor material layers 108. In some embodiments, the nitride layer 121 has a foot-like shaped structure.

Next, the source/drain (S/D) regions of the fin structure 104 are recessed to form source/drain (S/D) recesses 129, in in accordance with some embodiments. More specifically, the first semiconductor material layers 106 and the second semiconductor material layers 108 not covered by the dummy gate structure 118 and the gate spacer layers 126 are removed, in accordance with some embodiments.

In some embodiments, the first fin structure 104a and the second fin structure 104b are recessed by performing an etching process. The etching process may be an anisotropic etching process, such as dry plasma etching, and the first dummy gate structure 118, and the gate spacer layers 126 are used as etching masks during the etching process.

Afterwards, as shown in FIGS. 2F-1, 2F-2 and 2F-3, after the source/drain (S/D) recesses 129 are formed, a portion of the first semiconductor material layers 106 exposed by the S/D recesses 129 are laterally recessed to form notches (not shown), in accordance with some embodiments.

In some embodiments, an etching process is performed on the semiconductor structure 100a to laterally recess the first semiconductor material layers 106 of the fin structure 104 from the S/D recesses 129. In some embodiments, during the etching process, the first semiconductor material layers 106 have a greater etching rate (or etching amount) than the second semiconductor material layers 108, thereby forming notches between adjacent second semiconductor material layers 108. In some embodiments, the etching process is an isotropic etching such as dry chemical etching, remote plasma etching, wet chemical etching, another suitable technique, and/or a combination thereof.

Next, inner spacers 132 are formed in the notches between the second semiconductor material layers 108, in accordance with some embodiments. The inner spacers 132 are configured to separate the source/drain (S/D) structures and the gate structures formed in subsequent manufacturing processes in accordance with some embodiments. The nitride layer 121 is directly above the inner spacer layer 132.

In some embodiments, the inner spacers 132 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the inner spacer layer 132 is formed by a deposition process, such as chemical vapor deposition (CVD) process, atomic layer deposition (ALD) process, another applicable process, or a combination thereof.

Next, the S/D structures 138 are formed in the S/D recesses 129, in accordance with some embodiments. In some embodiments, the top surface of the S/D structure 138 is higher than the top surface of the topmost second semiconductor material layers 108. In some embodiments, the top surface of the S/D structure 138 is higher than the top surface of the nitride layer 121. In some embodiments, the nitride layer 121 is in direct contact with the S/D structure 138.

In some embodiments, the top surface of the S/D structure 138 is higher than the top surface of the dummy gate dielectric layer 120.

In some embodiments, the source/drain (S/D) structure 138 is formed using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof. In some embodiments, the source/drain (S/D) structure 138 is made of any applicable material, such as Ge, Si, GaAs, AlGaAs, SiGe, GaAsP, SiP, SiC, SiCP, or a combination thereof.

In some embodiments, the source/drain (S/D) structure 138 is in-situ doped during the epitaxial growth process. For example, the first source/drain (S/D) structure 138 may be the epitaxially grown SiGe doped with boron (B). For example, the source/drain (S/D) structure 138 may be the epitaxially grown Si doped with carbon to form silicon: carbon (Si: C) source/drain features, phosphorous to form silicon: phosphor (Si: P) source/drain features, or both carbon and phosphorous to form silicon carbon phosphor (SiCP) source/drain features. In some embodiments, the source/drain (S/D) structure 138 is doped in one or more implantation processes after the epitaxial growth process.

Next, as shown in FIGS. 2G-1, 2G-2 and 2G-3, a contact etch stop layer (CESL) 140 is conformally formed to cover the S/D structures 138, and an interlayer dielectric (ILD) layer 142 is formed over the contact etch stop layer 140, in accordance with some embodiments.

In some embodiments, the contact etch stop layer 140 is made of a dielectric materials, such as silicon nitride, silicon oxide, silicon oxynitride, another suitable dielectric material, or a combination thereof. The dielectric material for the contact etch stop layer 140 may be conformally deposited over the semiconductor structure by performing chemical vapor deposition (CVD), ALD, other application methods, or a combination thereof.

The ILD layer 142 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The ILD layer 142 may be formed by chemical vapor deposition (CVD), physical vapor deposition, (PVD), atomic layer deposition (ALD), or other applicable processes.

After the contact etch stop layer 140 and the ILD layer 142 are deposited, a planarization process such as CMP or an etch-back process may be performed until the dummy gate electrode layers 120 of the dummy gate structure 118 are exposed, as shown in FIG. 2G-1 in accordance with some embodiments.

Afterwards, as shown in FIGS. 2H-1, 2H-2 and 2H-3, the dummy gate electrode layer 122 of the dummy gate structure 118 is removed to form a trench 145, in accordance with some embodiments. As a result, the gate spacer layer 126 and the dummy gate dielectric layer 120 is exposed by the trench 145.

The removal process may include one or more etching processes. For example, when the dummy gate electrode layer 122 is polysilicon, a wet etchant such as a tetramethylammonium hydroxide (TMAH) solution may be used to selectively remove the dummy gate electrode layer 122.

Afterwards, as shown in FIGS. 2I-1, 2I-2 and 2I-3, the dummy gate dielectric layer 120 is removed to expose the nitride layer 121, in accordance with some embodiments. In some embodiments, the dummy gate dielectric layer 120 may be removed using a plasma dry etching, a dry chemical etching, and/or a wet etching.

It should be noted that the composition of the nitride layer 121 is different from that of the dummy gate dielectric layer 120. In addition, the nitride layer 121 has a high etching selectively with respect to the dummy gate dielectric layer 120. The etching resistance of the nitride layer 121 is better than that of the dummy gate dielectric layer 120. Therefore, the nitride layer 121 is not removed while the dummy gate dielectric layer 120 is removed. The nitride layer 121 is used as a protection layer.

The nitride layer 121 is directly below the gate spacer layer 126. In some embodiments, the nitride layer 121 has a triangular shaped like structure. In some embodiments, the nitride layer 121 has a foot-like shaped structure.

Afterwards, as shown in FIGS. 2J-1, 2J-2 and 2J-3, the first semiconductor material layers 106 are removed to form nanostructures 108′ (or channel layers 108′) with the second semiconductor material layers 108, in accordance with some embodiments. As a result, a number of gaps 147 are formed between the nanostructures 108′ (or channel layers 108′).

The first S/D structure 138 is attached to the nanostructures 108′. The first fin structure 104a and the second fin structure 104b include the nanostructures 108′.

The first semiconductor material layers 106 may be removed by performing a selective wet etching process, such as APM (e.g., ammonia hydroxide-hydrogen peroxide-water mixture) etching process. For example, the wet etching process uses etchants such as ammonium hydroxide (NH₄OH), TMAH, ethylenediamine pyrocatechol (EDP), and/or potassium hydroxide (KOH) solutions.

Next, as shown in FIGS. 2K-1, 2K-2 and 2K-3, after the nanostructures 108′ are formed, a gate structure 150a are formed to surround the nanostructures 108′ and over the isolation structure 116, in accordance with some embodiments.

After the nanostructures 108′ are formed, the gate structure 150 is formed wrapped around the nanostructures 108′. The gate structure 150 wraps around the nanostructures 108′ to form gate-all-around transistor structures, in accordance with some embodiments. In some embodiments, the gate structure 150 includes an interfacial layer (not shown), a gate dielectric layer 154, and a gate electrode layer 156.

In some embodiments, the interfacial layer (not shown) are oxide layers formed around the nanostructures 108′ and on the top of the base fin structure 105. In some embodiments, the interfacial layer are formed by performing a thermal process.

In some embodiments, the gate dielectric layers 154 are formed over the interfacial layers, so that the nanostructures 108′ are surrounded (e.g. wrapped) by the gate dielectric layers 154. In addition, the gate dielectric layers 154 also cover the sidewalls of the gate spacers 126 and the inner spacers 132 in accordance with some embodiments.

In some embodiments, the gate dielectric layers 154 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al2O₃) alloy, another suitable high-k dielectric material, or a combination thereof. In some embodiments, the gate dielectric layers 154 are formed using chemical vapor deposition (CVD), atomic layer deposition (ALD), another applicable method, or a combination thereof.

In some embodiments, the gate electrode layer 156 is made of one or more layers of conductive material, such as aluminum, copper, titanium, tantalum, tungsten, cobalt, molybdenum, tantalum nitride, nickel silicide, cobalt silicide, TiN, WN, TiAl, TiAIN, TaCN, TaC, TaSiN, metal alloys, another suitable material, or a combination thereof. In some embodiments, the gate electrode layer 156 is formed using chemical vapor deposition (CVD), atomic layer deposition (ALD), electroplating, another applicable method, or a combination thereof.

Other conductive layers, such as work function metal layers, may also be formed in the gate structure 150, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

After the interfacial layer (not shown), the gate dielectric layers 154, and the gate electrode layer 156 are formed, a planarization process such as CMP or an etch-back process may be performed until the ILD layer 142 is exposed.

As shown in FIG. 2K-1, the nitride layer 121 is directly below the gate spacer layer 126, and is not removed when the dummy gate dielectric layer 120 is removed. The nitride layer 121 is in direct contact with the S/D structure 138. The nitride layer 121 is in direct contact with the topmost nanostructure 108′. The interfacial layer (not shown) of the gate structure 150 is in direct contact with the nitride layer 121.

In addition, the gate structure 150 is separated from the S/D structure 138 by the nitride layer 121 and the gate spacer layer 126. The nitride layer 121 is not removed when the dummy gate dielectric layer 120 is removed. The risk of the leakage between the gate structure 150 and the S/D structure 138 is reduced due to the formation of the nitride layer 121. Therefore, the performance and the reliability of the semiconductor structure 100a is improved.

FIG. 2K′-1 illustrates a cross-sectional view of a semiconductor structure 100b, in accordance with some embodiments. The semiconductor structure 100b of FIG. 2K′-1 includes elements that are similar to, or the same as, elements of the semiconductor structure 100a of FIG. 2K-1, the difference between the FIG. 2K′-1 and FIG. 2K-1 is that the shape of the nitride layer 121 in FIG. 2K′-1 has a smooth sidewall surface.

FIGS. 3A-1 to 3O-1 illustrate cross-sectional representations of various stages of manufacturing a semiconductor structure 100c along a first direction (similar to line X-X′) of FIG. 1D, in accordance with some embodiments. FIGS. 3A-2 to 3O-2 illustrate cross-sectional representations of various stages of manufacturing the semiconductor structure 100c along a second direction (similar to line Y-Y′ of FIG. 1D), in accordance with some embodiments. The first direction is normal to the second direction. The semiconductor structure 100c of FIGS. 3A-1 to 3O and 3A-2 to 3O-2 and includes elements that are similar to, or the same as, elements of the semiconductor structure 100a of FIGS. 2A-1-2K-1, 2A-2-2K-2 and 2A-3-2K-3.

As shown in FIGS. 3A-1 and 3A-2, a first fin structure 103a is formed over a substrate 102, a sacrificial layer 109 is formed over the first fin structure 103a and a second fin structure 103b is formed over the sacrificial layer 109, in accordance with some embodiments. The semiconductor structure 100c is used to form CFET devices in which n-type devices and p-type devices are stacked.

The first fin structure 103a includes the first semiconductor layers 106B and the second semiconductor layers 108B are alternatively stacked. The second fin structure 103b includes the first semiconductor layers 106T and the second semiconductor layers 108T are alternatively stacked. The sacrificial layer 109 is made of first semiconductor layers. The first semiconductor layers 106B and the second semiconductor layers 108B are made of different materials. The first semiconductor layers 106T and the second semiconductor layers 108T are made of different materials. The first semiconductor layers 106B and 106T has a different lattice constant than the second semiconductor layers 108B and 108T, in accordance with some embodiments. In some embodiments, the first semiconductor layers 106B and 106T and the second semiconductor layers 108B and 108T have different oxidation rates and/or etching selectivity.

In some embodiments, the first semiconductor material layers 106B, 106T are made of SiGe, and the second semiconductor material layers 108B, 108T are made of silicon. In some embodiments, the sacrificial layer 109 is made of SiGe. In some embodiments, the concentration of the germanium (Ge) of the sacrificial layer 109 is higher that of the first semiconductor material layers 106B, 106T.

The first fin structure 103a and the second fin structure 103b are formed using an epitaxial growth process, in accordance with some embodiments. The epitaxial growth process may be molecular beam epitaxy (MBE), metal organic chemical vapor deposition (MOCVD), vapor phase epitaxy (VPE), or another suitable technique.

The sacrificial layer 109 is formed between the bottom device region and the top device region, in accordance with some embodiments. The bottom device region includes the semiconductor layers 106B and 108B while the top device region includes the semiconductor layers 106T and 108T, in accordance with some embodiments.

In some embodiments, the bottom device region is used to form p-type devices (e.g., p-channel nanostructure transistors), and the top device region is used to form n-type devices (e.g., n-channel nanostructure transistors). In some other embodiments, the bottom device region is used to form n-type devices (e.g., n-channel nanostructure transistors), and the top device region is used to form p-type devices (e.g., p-channel nanostructure transistors).

Afterwards, the hard mask layer 110 is formed on the second fin structure 103b, and a patterning process is performed on the second fin structure 103b and the sacrificial layer 109. The patterning process includes photolithography processes and etching processes. As a result, the second fin structure 103b is narrowed along the second direction (e.g. Y-axis) to form a patterned second fin structure 103b.

Next, as shown in FIGS. 3B-1 and 3B-2, a spacer layer 114 is formed on the hard mask layer 110 and the patterned second fin structure 103b, in accordance with some embodiments. More specifically, the spacer layer 114 is formed on the exposed top surface of the topmost first semiconductor layer 106B.

In some embodiments, the spacer layer 114 is made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. In some embodiments, the spacer layer 114 is formed by chemical vapor deposition (CVD), physical vapor deposition, (PVD), atomic layer deposition (ALD), or other applicable processes.

Afterwards, as shown in FIGS. 3C-1 and 3C-2, the first fin structure 103a and a portion of the substrate 102 are patterned by using the spacer layer 114 as the mask, in accordance with some embodiments. As a result, the first fin structure 103a is narrowed along the second direction (e.g. Y-axis) to form a patterned first fin structure 103a. The patterning process includes photolithography processes and etching processes.

Next, as shown in FIGS. 3D-1 and 3D-2, the spacer layer 114 is removed, and the isolation material is formed on the patterned first fin structure 103a and the patterned second fin structure 103b, in accordance with some embodiments.

A planarization process is performed on the isolation material to remove a portion of the isolation material. The planarization may be chemical mechanical polishing (CMP), an etching back process, or a combination thereof. Next, the hard mask layer 110 is removed, and the isolation material is then recessed by an etching process (such as dry plasma etching and/or wet chemical etching) to expose the sidewall surfaces of the patterned first fin structure 103a and the patterned second fin structure 103b. As a result, the isolation structure 116 is formed. The isolation structure 116 is referred to as shallow trench isolation (STI) feature, in accordance with some embodiments.

Next, as shown in FIGS. 3E-1 and 3E-2, after the isolation structure 116 is formed, dummy gate structures 118 are formed across the patterned first fin structure 103a, the sacrificial layer 109 and the patterned second fin structure 103b. In some embodiments, the dummy gate structures 118 extend in the second direction (e.g. Y-axis). That is, the dummy gate structures 118 have longitudinal axes parallel to the second direction (e.g. Y-axis), in accordance with some embodiments. The dummy gate structures 118 are configured as sacrificial structures and will be replaced with the final gate stacks, in accordance with some embodiments.

It should be noted that the dummy gate structure 118 is formed by patterning the dummy gate dielectric layer 120 and the dummy gate electrode layer 122 to form a patterned dummy gate dielectric layer 120 and the patterned dummy gate electrode layer 122. The patterned dummy gate dielectric layer 120 includes a protruding portion 120P. The protruding portion 120P of the dummy gate dielectric layer 120 protrudes from the sidewall surface of the patterned dummy gate electrode layer 122.

Next, as shown in FIGS. 3F-1 and 3F-2, after the dummy gate structures 118 are formed, the nitridation process is performed on the protruding portion of the dummy gate dielectric layer 120, in accordance with some embodiments. As a result, the nitride layer 121 is formed. Next, the gate spacer layer 126 is formed along and covering opposite sidewalls of the dummy gate structure 118. More specifically, the gate spacer layer 126 is directly formed on the nitride layer 121.

Next, after the gate spacer layer 126 is formed, the source/drain (S/D) regions are recessed to form source/drain (S/D) recesses 129, as shown in in accordance with some embodiments. More specifically, the first semiconductor material layers 106B and 106T and the second semiconductor material layers 108B and 108T not covered by the dummy gate structures 118 and the gate spacer layers 126 are removed, in accordance with some embodiments.

Afterwards, as shown in FIGS. 3G-1 and 3G-2, the sacrificial layer 109 is removed to form a recess 130, in accordance with some embodiments. The recess 130 is connected to the S/D recess 129. In some embodiments, the sacrificial layer 109 is removed by an etching process, such as dry etching process or wet etching process.

Next, as shown in FIGS. 3H-1 and 3H-2, a middle dielectric layer 131 is formed in the recess 130 and in the S/D recess 129, in accordance with some embodiments.

It should be noted that the middle dielectric layer 131 and the gate spacer layer 126 are made of different materials. The middle dielectric layer 131 has a high etching selectivity with respect to the gate spacer layer 126. When the middle dielectric layer 131 is removed while the gate spacer layer 126 is not removed in the following process. Furthermore, the middle dielectric layer 131 and the inner spacer layer 132 (formed later, as shown in FIG. 3J-1) are made of different materials. The middle dielectric layer 131 has a high etching selectivity with respect to the inner spacer layer 132. When the inner spacer layer 132 is removed, while the middle dielectric layer 131 is not removed in the following process.

It should be noted that the middle dielectric layer 131 is between the first fin structure 103a and the second fin structure 103b. More specifically, the middle dielectric layer 131 is between the first semiconductor layer 106B and the first semiconductor layer 106T. The middle dielectric layer 131 is between the second semiconductor layer 108B and the second semiconductor layer 108T.

In some embodiments, the middle dielectric layer 131 is made of silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), and/or a combination thereof. In some embodiments, the middle dielectric layer 131 is formed by a chemical vapor deposition (CVD), atomic vapor deposition (ALD), physical vapor deposition (PVD), or another suitable process.

Afterwards, as shown in FIGS. 3I-1 and 3I-2, a portion of the middle dielectric layer 131 outside of the recess 130 is removed, in accordance with some embodiments. The nitride layer 121 is directly above the middle dielectric layer 131. In some embodiments, the portion of the middle dielectric layer 131 is removed by an etching process, such as dry etching process or wet etching process.

As a result, the outer sidewall surfaces of the first semiconductor layers 106B, 106T are aligned with the outer sidewall surfaces of the middle dielectric layer 131. In addition, the outer sidewall surfaces of the second semiconductor layers 108B, 108T are aligned with the outer sidewall surfaces of the middle dielectric layer 131.

Next, as shown in FIGS. 3J-1 and 3J-2, after the middle dielectric layer 131 are formed, the first semiconductor layers 106B, 106T exposed by the S/D recesses 129 are laterally recessed to form notches (not shown), and inner spacer layers 132 are formed in the notches between the second semiconductor layers 108B, 108T, in accordance with some embodiments. The sidewall surface of the inner spacer layer 132 is aligned with a sidewall surface of the first middle dielectric layer 131. The sidewall surface of the inner spacer layer 132 is aligned with the sidewall surface of the nitride layer 121.

It should be noted that the middle dielectric layer 131 and the inner spacer layer 132 are made of different materials. The middle dielectric layer 131 has a high etching selectivity with respect to the inner spacer layer 132. When a portion of the inner spacer layer 132 outside of the notches is removed, the middle dielectric layer 131 is not removed.

Afterwards, as shown in FIGS. 3K-1 and 3K-2, a bottom layer 133 is formed in the S/D recess 129, in accordance with some embodiments. In some embodiments, the bottom layer 133 include un-doped Si, un-doped SiGe or a combination thereof. In some embodiments, the bottom layer 133 is formed by an epitaxy or epitaxial (epi) process. The epi process may include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epi processes.

Next, a first S/D structure 134 is formed on the bottom layer 133, in accordance with some embodiments. In some embodiments, when an N-type FET (NFET) device is desired, the first S/D structure 134 includes an epitaxially growing silicon (epi Si). Alternatively, when a P-type FET (PFET) device is desired, the first S/D structure 134 includes an epitaxially growing silicon germanium (SiGe).

Next, as shown in FIGS. 3L-1 and 3L-2, a contact etching stop layer 135 is formed over the first S/D structure 134, in accordance with some embodiments. In some embodiments, the top surface of the contact etching stop layer 135 is higher than the top surface of the middle dielectric layer 131. A spacer dielectric layer 136 is formed over the contact etching stop layer 135. The first spacer dielectric layer 136 overfills the space between dummy gate structures 118.

In some embodiments, the spacer dielectric layer 136 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material. In some embodiments, the spacer dielectric layer 136 and the contact etching stop layer 135 are made of different materials and have a great difference in etching selectivity.

Afterwards, a second S/D structure 138 is formed on the spacer dielectric layer 136, in accordance with some embodiments. As a result, the spacer dielectric layer 136 is between the first S/D structure 134 and the second S/D structure 138.

Next, as shown in FIGS. 3M-1 and 3M-2, a contact etching stop layer 140 is formed over the second S/D structure 138, and an interlayer dielectric layer 142 is formed on the contact etching stop layer 140, in accordance with some embodiments.

Next, as shown in FIGS. 3N-1 and 3N-2, the dummy gate electrode layer 122 and the dummy gate dielectric layer 120 are removed to form a trench 145, in accordance with some embodiments. Next, the first semiconductor layer 106B and 106T are removed to form a number of gaps 147. As a result, the nanostructures 108B and 108T (or channel layers 108B and 108T) with the second semiconductor material layers 108 are obtained. The number of nanostructures 108B and 108T (or channel layers 108B and 108T) may be adjusted according to actual application. In addition, the middle dielectric layer 131 is exposed by the trench 145 and the gaps 147.

It should be noted that the nitride layer 121 is not removed while the dummy gate dielectric layer 120 is removed. The nitride layer 121 is still directly below the gate spacer layer 126 to as the protective layer.

As shown in FIG. 3N-2, the second semiconductor layer 108B of the first fin structure 103a of the bottom transistor BT has a first width W1 along the second direction (e.g. Y-axis), the second semiconductor layer 108T of the second fin structure 103b of the of the top transistor TT has a second width W2 along the second direction (e.g. Y-axis). The middle dielectric layer 131 has a third width W3 along the second direction (e.g. Y-axis). In some embodiments, the first width W1 of the second semiconductor layer 108B is greater than the second width W2 of the second semiconductor layer 108T. In some embodiments, the third width W3 of the middle dielectric layer 130 is greater than the second width W2 of the second semiconductor layer 108T. In some embodiments, the third width W3 of the middle dielectric layer 130 is substantially equal to the first width W1 of the second semiconductor layer 108B.

In some other embodiments, if the steps of FIGS. 3B-1, 3B-2, 3C-1 and 3C-2 are omitted, the first width W1 of the second semiconductor layer 108B is equal to the second width W2 of the second semiconductor layer 108T. In some embodiments, the third width W3 of the middle dielectric layer 131 is equal to the second width W2 of the second semiconductor layer 108T.

Afterwards, as shown in FIGS. 3O-1 and 3O-2, after the nanostructures 108′ are formed, a first gate structure 150a and a second gate structure 150b are formed to surround the nanostructures 108′ and over the isolation structure 116, in accordance with some embodiments.

The first gate structure 150a is a first type gate structure, and the second gate structure 150b is a second type gate structure. In some embodiments, the first gate structure 150a is an N-type gate structure, and the second gate structure 150b is a P-type gate structure. In some embodiments, the first gate structure 150a is a P-type gate structure, and the second gate structure 150b is an N-type gate structure. The first gate structure 150a and the second gate structure 150b extend in the second direction (e.g. Y-axis). The first gate structure 150a and the second gate structure 150b have longitudinal axes parallel to the Y direction, in accordance with some embodiments.

In some embodiments, the n-channel top transistors TT are directly stacked above the p-channel bottom transistors BT thereby constructing CFET. In some embodiments, the p-channel top transistors TT are directly stacked above the n-channel bottom transistors BT thereby constructing CFET.

In some embodiments, the first gate structure 150a includes an interfacial layer (not shown), a gate dielectric layer 154, and a first gate electrode layer 156a. In some embodiments, the second gate structure 150b includes an interfacial layer (not shown), a gate dielectric layer 154, and a second gate electrode layer 156b.

In accordance with the embodiments of the present disclosure, each of the CFET devices of the semiconductor structure 100a includes a bottom transistor BT and a top transistor TT directly above the bottom transistor BT.

The large effective width (W_{eff}) of channel layer (e.g. nanostructures 108B) can provide high speed and high driving current of the semiconductor structure 100c. However, the larger effective width of the channel layer consumes more power. For high-speed performance consideration, larger effective width (W_{eff}) is formed by having more nanostructures. For power efficiency, a smaller effective width (W_{eff}) (e.g. nanostructures 108T) is formed by having fewer nanostructures. Thus, the performance of the top transistor TT and that of the bottom transistor BT can be independently adjusted.

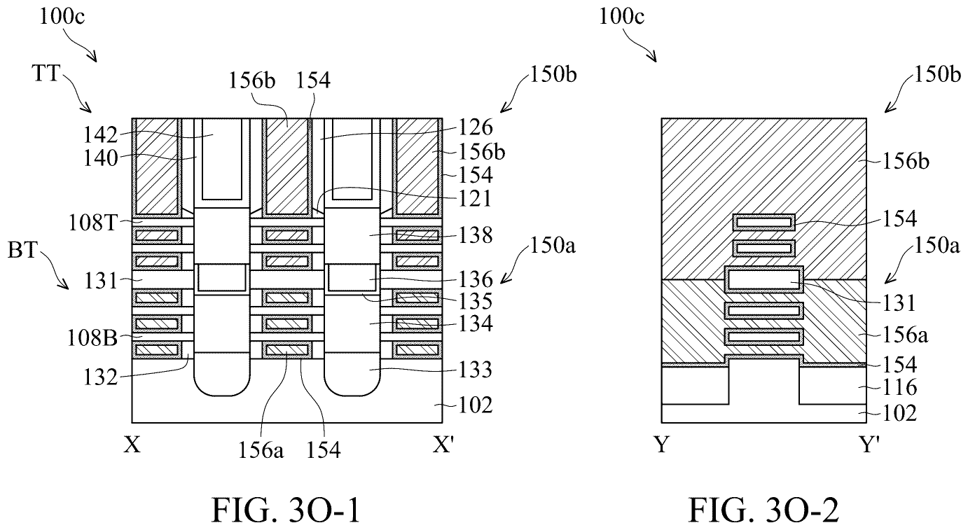

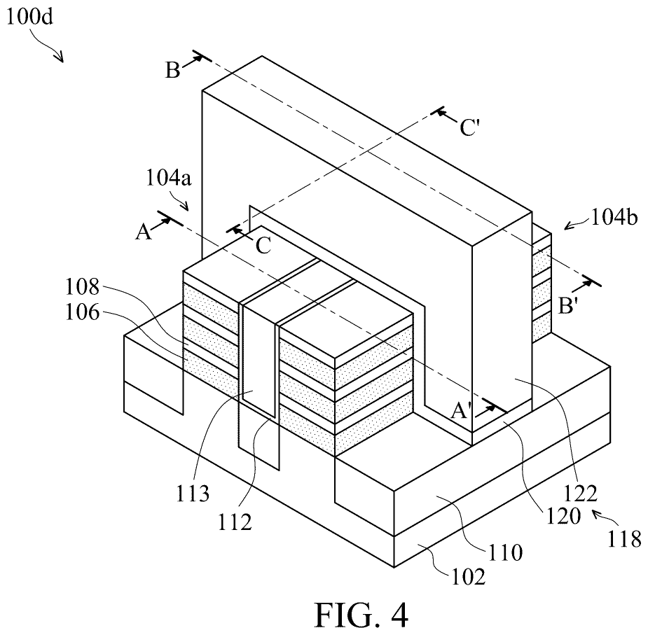

FIG. 4 show perspective views of a semiconductor structure 100d, in accordance with some embodiments. The semiconductor structure 100d of FIG. 4 includes elements that are similar to, or the same as, elements of the semiconductor structure 100a of FIGS. 1A-1D, 2A-1-2K-1, 2A-1-2K-2 and 2A-3-2K-3.

As shown in FIG. 4, the first fin structure 104a and the second fin structure 104b are formed over the substrate 102. The first fin structure 104a includes first semiconductor material layers 106 and second semiconductor material layers 108 alternatively stacked. The second fin structure 104b includes first semiconductor material layers 106 and second semiconductor material layers 108 alternatively stacked.

After the first fin structure 104a and the second fin structure 104b are formed, the isolation structure 116 is formed around the first fin structure 104a and the second fin structure 104b.

Next, a liner dielectric layer 112 is formed over the first fin structure 104a and the second fin structure 104b, and a core dielectric layer 113 is formed over the liner dielectric layer 112. The liner dielectric layer 112 is an adhesion layer to improve the adhesion between the core dielectric layer 113 and the first fin structure 104a and the second fin structure 104b.

Next, a portion of the liner dielectric layer 112 and a portion of the core dielectric layer 113 are removed to form a dielectric wall 115 between two adjacent first fin structure 104a and the second fin structure 104b, in accordance with some embodiments. More specifically, the dielectric wall 115 is in direct contact with the first semiconductor layers 106 and the second semiconductor layers 108. The dielectric wall 115 is in direct contact with the isolation structure 110.

In some embodiments, the liner dielectric layer 112 is made of oxide, such as silicon oxide. In some embodiments, the liner dielectric layer 112 is formed by chemical vapor deposition (CVD), atomic vapor deposition (ALD), physical vapor deposition (PVD), another suitable method, or a combination thereof. In some embodiments, the core dielectric layer 113 is made of SiN, SiCN, SiOC, SiOCN or applicable material. In some embodiments, the core dielectric layer 113 is formed by chemical vapor deposition (CVD), atomic vapor deposition (ALD), physical vapor deposition (PVD), another suitable method, or a combination thereof.

After the dielectric wall 115 is formed, the dummy gate structure 118 is formed across the first fin structure 104a and the second fin structure 104b and extends over the isolation structure 116, in accordance with some embodiments.

The dummy gate structures 118 may be used to define the source/drain (S/D) regions and the channel regions of the resulting semiconductor structure 100a. In some embodiments, the dummy gate structures 118 include the dummy gate dielectric layer 120 and the dummy gate electrode layer 122.

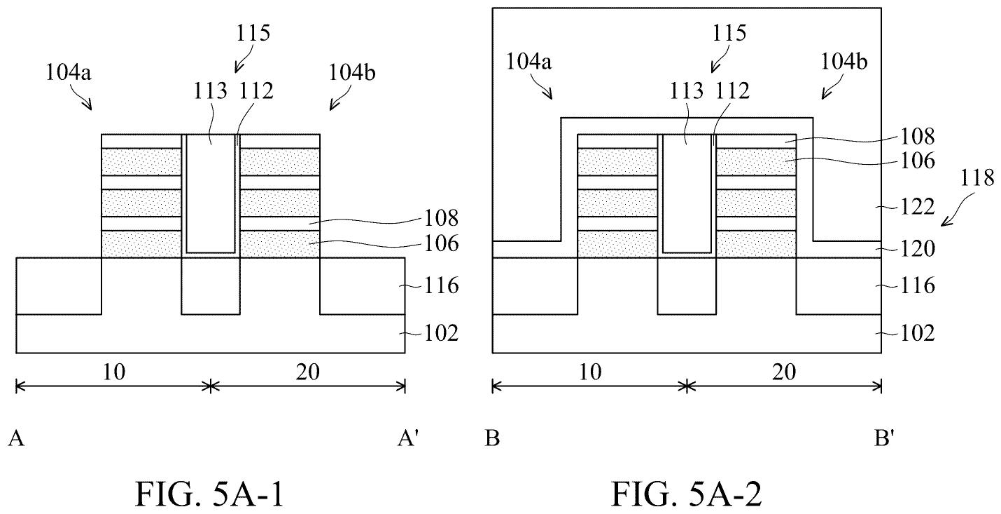

FIG. 5A-1 shows the cross-sectional representation shown along line A-A′ in FIG. 4, in accordance with some embodiments. FIG. 5A-2 shows the cross-sectional representation shown along line B-B′ in FIG. 4, in accordance with some embodiments. FIG. 5A-1 shows an S/D region and FIG. 5A-2 shows a gate structure region.

As shown in FIGS. 5A-1 and 5A-2, the substrate 102 includes a first region 10 and a second region 20. The first fin structure 104a is formed in the first region 10, and the second fin structure 104b is formed in the second region 20. The dielectric wall 115 is between and in direct contact with the first fin structure 104a and the second fin structure 104b. The liner dielectric layer 112 is in direct contact with the first semiconductor layers 106 and the second semiconductor layers 108. The liner dielectric layer 112 has a U-shaped structure. The dummy gate structure 118 is formed across the first fin structure 104a and the second fin structure 104b and over the dielectric wall 115. The dummy gate structure 118 includes the dummy gate dielectric layer 120 and the dummy gate electrode layer 122.

Next, the semiconductor structure 100d may undergo the various processes that are similar to the processes shown in FIGS. 2A-1-2K-1, 2A-1-2K-2 and 2A-3-2K-3 to form semiconductor structure 100d in FIGS. 6A-1, 6A-2 and 6A-3. The protruding portion of the dummy gate dielectric layer 120 is nitride to form the nitride layer 121. The nitride layer 121 is not removed when the dummy gate dielectric layer 120 is removed. The gate structure 150a is separated from the S/D structure 138 by the nitride layer 121 and the gate spacer layer 126.

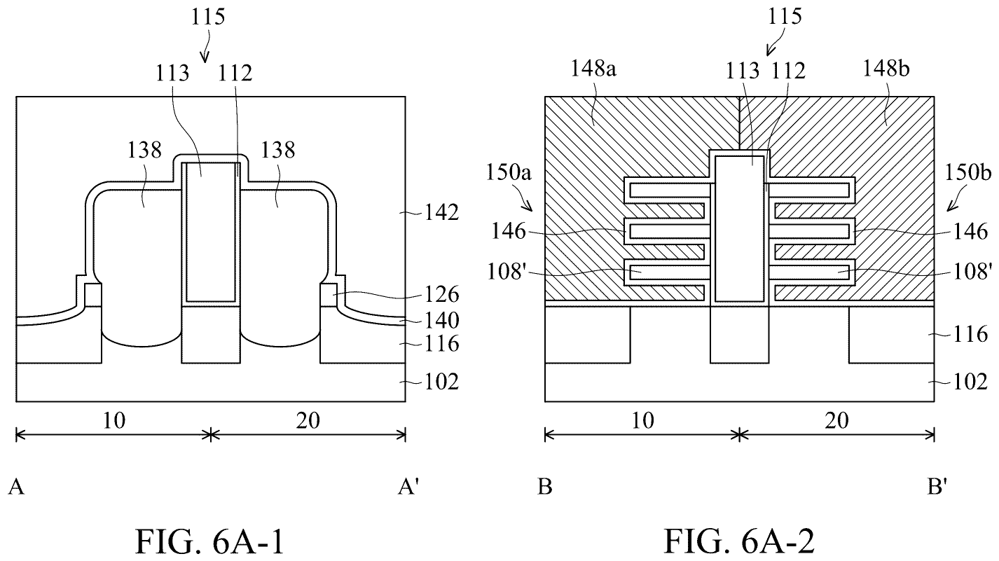

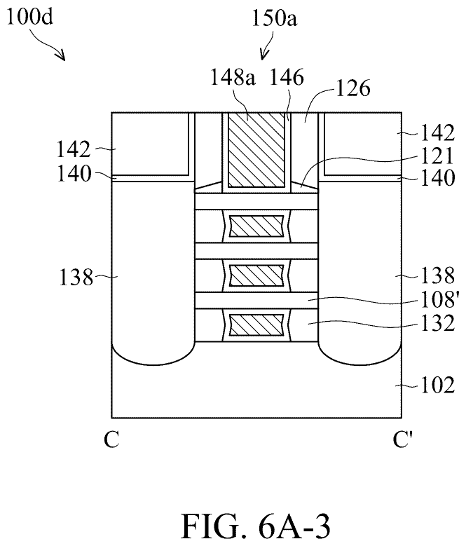

FIG. 6A-1 shows the cross-sectional representation shown along line A-A′ in FIG. 4, in accordance with some embodiments. FIG. 6A-2 shows the cross-sectional representation shown along line B-B′ in FIG. 4, in accordance with some embodiments. FIG. 6A-3 shows the cross-sectional representation shown along line C-C′ in FIG. 4, in accordance with some embodiments.

As shown in FIG. 6A-1, the S/D structures 138 are formed in the first region 10 and the second region 20, in accordance with some embodiments. The top surface of the dielectric wall 115 is higher than the top surfaces of the S/D structures 138. After the t S/D structures 138 are formed, the contact etch stop layer (CESL) 140 is conformally formed to cover the S/D structures 138 and the interlayer dielectric (ILD) layer 140 is formed over the contact etch stop layers 138, in accordance with some embodiments.

As shown in FIG. 6A-2, the first gate electrode layer 150a is formed in the first region 10 to surround the nanostructures 108′, and the second gate electrode layer 150b is formed in the second region 20 to surround the nanostructures 108′, in accordance with some embodiments.

The first gate structure 142a is constructed by the interfacial layer (not shown), the gate dielectric layer 146, and the first gate electrode layer 148a. The second gate structure 142b is constructed by the interfacial layer (not shown), the gate dielectric layer 146, and the second gate electrode layer 148b. The material of the second gate electrode layer 148b is different from that of the first gate electrode layer 148a. There is an interface between the first gate electrode layer 148a and the second gate electrode layer 148b.

As shown in FIG. 6A-3, the nitride layer 121 is directly below the gate spacer layer 126, and the nitride layer 121 is in direct contact with the S/D structure 138 and the topmost nanostructure 108′. The gate structure 150 is separated from the S/D structure 138 by the nitride layer 121 and the gate spacer layer 126. The risk of the leakage between the gate structure 150 and the S/D structure 138 is reduced due to the formation of the nitride layer 121. Therefore, the performance and the reliability of the semiconductor structure 100a is improved.

The nitride layer 121 can be used in GAA device (as shown in FIGS. 2A-1-2K-1, 2A-2-2K-2 and 2A-3-2K-3), the CFET device (as shown in FIGS. 3A-1-3O-1 and 3A-2-3O-2) or fork-sheet device (FIGS. 4, 5A-1, 5A-2, 6A-1, 6A-2 and 6A-3). The etching resistance of the nitride layer 121 is better than that of the dummy gate dielectric layer 120. Therefore, the nitride layer 121 is not removed when the dummy gate dielectric layer 120 is removed. The nitride layer 121 can be a protective layer. The gate structure 150 can be separated from the S/D structure 138 by the nitride layer 121 and the gate spacer layer 126. Therefore, the unwanted leakage between the gate structure 150 and the S/D structure 138 can be reduced. Therefore, the performance and the reliability of the semiconductor structure is improved.

It should be appreciated that the semiconductor structures 100a to 100d having different number of nanostructures 108′ (or channel layers) in different region for performing different functions described above may also be applied to FinFET structures, although not shown in the figures.

It should be noted that same elements in FIGS. 1A to 6A-3 may be designated by the same numerals and may include similar or the same materials and may be formed by similar or the same processes; therefore such redundant details are omitted in the interest of brevity. In addition, although FIGS. 1A to 6A-3 are described in relation to the method, it will be appreciated that the structures disclosed in FIGS. 1A to 6A-3 are not limited to the method but may stand alone as structures independent of the method. Similarly, although the methods shown in FIGS. 1A to 6A-3 are not limited to the disclosed structures but may stand alone independent of the structures. Furthermore, the nanostructures described above may include nanowires, nanosheets, or other applicable nanostructures in accordance with some embodiments.

Also, while disclosed methods are illustrated and described below as a series of acts or events, it will be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming semiconductor structures may be provided. The semiconductor structure includes a first fin structure and a second fin structure formed over a substrate. The semiconductor structures may include a fin structure formed over a substrate. The fin structure includes nanostructures. A gate structure formed over the first nanostructures and a first S/D structure adjacent to the gate structure. A gate spacer layer is adjacent to the gate structure, and a nitride layer is directly below the gate spacer layer. The composition of the nitride layer is different from that of the gate spacer layer. The nitride layer is formed by performing a nitridation process on the dummy gate dielectric layer. The nitride layer is not removed during the dummy gate dielectric layer is removed. The gate structure is separated from the S/D structure by the nitride layer and the gate spacer layer. The risk of the leakage between the gate structure and the S/D structure is reduced due to the formation of the nitride layer. Therefore, the performance and the reliability of the semiconductor structure is improved.

In some embodiments, a method for forming a semiconductor structure is provided. The method includes forming a first fin structure over a substrate, and forming a dummy gate dielectric layer over the first fin structure. The method includes forming a dummy gate electrode layer over the dummy gate dielectric layer, and patterning the dummy gate electrode layer and the dummy gate dielectric layer to form a patterned dummy gate electrode layer and a patterned dummy gate dielectric layer. The patterned dummy gate dielectric layer includes a protruding portion, and the protruding portion of the dummy gate dielectric layer protrudes from a sidewall surface of the patterned dummy gate electrode layer. The method also includes performing a nitridation process on the protruding portion of the dummy gate dielectric layer, such that the protruding portion of the dummy gate dielectric layer becomes a nitride layer. The method includes forming a gate spacer layer on the nitride layer and a sidewall surface of the dummy gate electrode layer. The method includes removing the dummy gate electrode layer, and removing the dummy gate dielectric layer to expose the nitride layer. The method includes forming a gate structure on the first fin structure.

In some embodiments, a method for forming a semiconductor structure is provided. The method includes forming a first fin structure over a substrate, and first fin structure comprises semiconductor material layers and second semiconductor material layers alternately stacked. The method includes forming a dummy gate dielectric layer over the first fin structure, and forming a dummy gate electrode layer over the dummy gate dielectric layer. The method includes patterning the dummy gate electrode layer and the dummy gate dielectric layer to form a protruding portion of the dummy gate dielectric layer. The method includes performing a treatment on the protruding portion of the dummy gate dielectric layer, such that the protruding portion becomes a nitride layer. The nitride layer has an inner sidewall surface and an outer sidewall surface, the inner sidewall surface has a first height along a vertical direction, and the outer sidewall surface has a second height along the vertical direction, and the first height is greater than the second height. The method includes forming a gate spacer layer on the nitride layer and a sidewall surface of the dummy gate structure, and forming an S/D recess adjacent to the dummy gate structure. The method includes forming an S/D structure in the S/D recess.

In some embodiments, a semiconductor structure is provided. The semiconductor structure includes a plurality of first nanostructures formed over a substrate, and a first gate structure formed over the first nanostructures. The semiconductor structure includes a gate spacer layer formed adjacent to the first gate structure, and a nitride layer formed adjacent to the first gate structure. The nitride layer is directly below the gate spacer layer. The nitrogen concentration of the nitride layer gradually decreases from the outer sidewall surface to the inner sidewall surface.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming a first fin structure over a substrate;
forming a dummy gate dielectric layer over the first fin structure;
forming a dummy gate electrode layer over the dummy gate dielectric layer;
patterning the dummy gate electrode layer and the dummy gate dielectric layer to form a patterned dummy gate electrode layer and a patterned dummy gate dielectric layer, wherein the patterned dummy gate dielectric layer comprises a protruding portion, and the protruding portion of the dummy gate dielectric layer protrudes from a sidewall surface of the patterned dummy gate electrode layer;
performing a nitridation process on the protruding portion of the dummy gate dielectric layer, such that the protruding portion of the dummy gate dielectric layer becomes a nitride layer;
forming a gate spacer layer on the nitride layer and a sidewall surface of the dummy gate electrode layer;
removing the dummy gate electrode layer;
removing the dummy gate dielectric layer to expose the nitride layer; and
forming a gate structure on the first fin structure.

2. The method for forming the semiconductor structure as claimed in claim 1, wherein the first fin structure comprises first semiconductor material layers and second semiconductor material layers alternately stacked.

3. The method for forming the semiconductor structure as claimed in claim 2, further comprising:
removing a portion of the first semiconductor material layers to form a notch; and
forming an inner spacer layer in the notch, wherein the nitride layer is directly above the inner spacer layer.

4. The method for forming the semiconductor structure as claimed in claim 1, further comprising:
forming an S/D structure adjacent to the first fin structure, wherein the gate structure is separated from the S/D structure by the nitride layer.

5. The method for forming the semiconductor structure as claimed in claim 1, wherein a sidewall surface of the nitride layer is aligned with a sidewall surface of the gate spacer layer.

6. The method for forming the semiconductor structure as claimed in claim 1, further comprising:
forming a middle dielectric layer over the first fin structure; and
forming a second fin structure over the middle dielectric layer, wherein the nitride layer is directly above the middle dielectric layer.

7. The method for forming the semiconductor structure as claimed in claim 6, wherein a width of the first middle dielectric layer is larger than a width of one of the second fin structures.

8. The method for forming the semiconductor structure as claimed in claim 1, further comprising:
forming a second fin structure adjacent to the first fin structure; and
forming a dielectric wall between the first fin structure and the second fin structure.

9. The method for forming the semiconductor structure as claimed in claim 1, wherein a nitrogen concentration of the nitride layer gradually decreases from an outer sidewall surface to an inner sidewall surface, and the inner sidewall surface is a sidewall surface that is in direct contact with the dummy gate dielectric layer.

10. A method for forming a semiconductor structure, comprising:
forming a first fin structure over a substrate, wherein first fin structure comprises first semiconductor material layers and second semiconductor material layers alternately stacked;
forming a dummy gate dielectric layer over the first fin structure;
forming a dummy gate electrode layer over the dummy gate dielectric layer;
patterning the dummy gate electrode layer and the dummy gate dielectric layer to form a protruding portion of the dummy gate dielectric layer;
performing a treatment on the protruding portion of the dummy gate dielectric layer, such that the protruding portion becomes a nitride layer, wherein the nitride layer has an inner sidewall surface and an outer sidewall surface, the inner sidewall surface has a first height along a vertical direction, and the outer sidewall surface has a second height along the vertical direction, and the first height is greater than the second height; and
forming a gate spacer layer on the nitride layer and a sidewall surface of the dummy gate structure;
forming an S/D recess adjacent to the dummy gate structure; and
forming an S/D structure in the S/D recess.

11. The method for forming the semiconductor structure as claimed in claim 10, wherein a nitrogen concentration of the nitride layer gradually decreases from the outer sidewall surface to the inner sidewall surface, and the inner sidewall surface is a sidewall surface that is in direct contact with the dummy gate dielectric layer.

12. The method for forming the semiconductor structure as claimed in claim 10, wherein the nitride layer is in direct contact with the S/D structure.

13. The method for forming the semiconductor structure as claimed in claim 10, further comprising:
removing the dummy gate structure; and
removing the dummy gate dielectric layer to expose the nitride layer, wherein the nitride layer is not removed during removing the dummy gate dielectric layer.

14. The method for forming the semiconductor structure as claimed in claim 10, wherein the nitride layer is in direct contact with a topmost second semiconductor material layer.

15. The method for forming the semiconductor structure as claimed in claim 10, further comprising:
forming a middle dielectric layer over the first fin structure; and
forming a second fin structure over the middle dielectric layer, wherein the nitride layer is directly above the middle dielectric layer.

16. The method for forming the semiconductor structure as claimed in claim 10, further comprising:
forming a second fin structure adjacent to the first fin structure; and
forming a dielectric wall between the first fin structure and the second fin structure.

17. A semiconductor structure, comprising:
a plurality of first nanostructures formed over a substrate;
a first gate structure formed over the first nanostructures;
a gate spacer layer formed adjacent to the first gate structure; and
a nitride layer formed adjacent to the first gate structure, wherein the nitride layer is directly below the gate spacer layer and a nitrogen concentration of the nitride layer gradually decreases from an outer sidewall surface to an inner sidewall surface.

18. The semiconductor structure as claimed in claim 17, further comprising:
an S/D structure formed adjacent to the first gate structure, wherein the nitride layer is separated from the S/D structure by the gate spacer layer.

19. The semiconductor structure as claimed in claim 17, further comprising:
a middle dielectric layer formed over the first fin structure; and
a second fin structure formed over the middle dielectric layer, wherein the nitride layer is directly above the middle dielectric layer.

20. The semiconductor structure as claimed in claim 17, further comprising:
a plurality of second nanostructures adjacent to the first fin structure; and
a dielectric wall between the first nanostructures and the second nanostructures.
